(19) United States
(12) Patent Application Publication
(10) Pub. No.: US 2025/0374624 A1
(43) Pub. Date: Dec. 4, 2025

(54) PASSIVE DEVICE INTEGRATED INTO BACKSIDE POWER DELIVERY NETWORK

(71) Applicant: INTERNATIONAL BUSINESS MACHINES CORPORATION, Armonk, NY (US)

(72) Inventors: Tsung-Sheng Kang, Ballston Lake, NY (US); Tao Li, Slingerlands, NY (US); Ruilong Xie, Niskayuna, NY (US); Robert Gauthier, Williston, VT (US); Anindya Nath, Watervliet, NY (US)

(21) Appl. No.: 18/731,188

(22) Filed: May 31, 2024

(51) Int. Cl. H01L 29/08; H01L 21/425; H01L 23/528; H01L 29/417; H01L 29/423; H01L 29/78

(52) U.S. Cl. CPC H10D 62/151; H01L 21/425; H01L 23/5286; H10D 64/254; H10D 64/518; H10D 30/60

(57) ABSTRACT

A semiconductor device includes a passive device including a channel region separating a first source/drain region (S/D) and a second S/D, a shallow trench isolation (STI) extended over the first S/D and the second S/D, and a gate region over the STI and the channel region. The first S/D is extended laterally between the channel region and a first end, and the second S/D is extended laterally between the channel region and a second end. Portions of the gate region are extended vertically through the STI and cover an upper surface of the channel region.

### BACKGROUND

### Technical Field

The present disclosure generally relates to semiconductors, and more particularly, to semiconductors with integrated passive device into backside power delivery network flow structure, and methods of creation thereof.

### Description of Related Art

The relentless miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. The evolution towards system-on-chip architectures integrates various functionalities, including processing and sensing, on one chip.

### SUMMARY

According to an embodiment, a semiconductor device includes a passive device including a channel region separating a first source/drain region (S/D) and a second S/D, a shallow trench isolation (STI) extended over the first S/D and the second S/D, and a gate region over the STI and the channel region. The first S/D is extended laterally between the channel region and a first end, and the second S/D is extended laterally between the channel region and a second end. Portions of the gate region are extended vertically through the STI and cover an upper surface of the channel region.

In an embodiment, the passive device includes a liner isolating the gate region from direct contact with the STI and the channel region.

In an embodiment, the channel region includes a silicon layer.

In an embodiment, the first S/D and the second S/D are doped with an extrinsic material configured to add resistance to the first S/D and the second S/D.

In an embodiment, the passive device includes a first backside contact coupled to a bottom surface of first S/D on the first end, and a second backside contact coupled to a bottom surface of second S/D on the second end.

In an embodiment, the first backside contact and the second backside contact couple the first S/D and the second S/D to a backside power delivery network (BSPDN), respectively.

In some embodiments, the passive device is an electro-static discharge (ESD) lateral NPN device, an EDS lateral PNP device, an ESD N-channel field-effect transistor (NFET), an ESD P-Channel FET (PFET), or a bipolar junction transistor (BJT).

In an embodiment, the semiconductor device includes a logic device electrically coupled to the passive device.

According to an embodiment, a method for fabrication of a semiconductor device includes forming a passive device including forming a first source/drain region (S/D) and a second S/D, isolating the first S/D and the second S/D by the channel region, forming a gate region above the first S/D and the second S/D, forming the first S/D extended laterally between the channel region and a first end, forming the second S/D extended laterally between the channel region and a second end, forming a shallow trench isolation (STI) extended laterally over the first S/D and the second S/D, and covering an upper surface of the channel region by vertically protruding portions of the gate region through the STI.

In an embodiment, the method includes forming a liner isolating the gate region from direct contact with the STI and the channel region.

In an embodiment, the method includes doping the first S/D and the second S/D with an extrinsic material configured to add resistance to the first S/D and the second S/D.

In an embodiment, the method includes electrically coupling a first backside contact to a bottom surface of first S/D on the first end, and electrically coupling a second backside contact to a bottom surface of second S/D on the second end.

In an embodiment, the method includes electrically coupling the first backside contact and the second backside contact to the first S/D and the second S/D to a backside power delivery network (BSPDN), respectively.

In an embodiment, the method includes forming a logic device electrically coupled to the passive device.

In accordance with an embodiment, a semiconductor device includes a passive device including a channel region separating a first source/drain region (S/D) and a second S/D, a gate region over the channel region, a first backside contact coupled to a bottom surface of first S/D on the first end, and a second backside contact coupled to a bottom surface of second S/D on the second end. The first S/D is extended laterally between the channel region and a first end, and the second S/D is extended laterally between the channel region and a second end. Portions of the gate region cover an upper surface of the channel region.

In an embodiment, the semiconductor device includes a shallow trench isolation (STI) extended over the first S/D and the second S/D. The gate region is extended over the STI, and portions of the gate region are extended vertically through the STI.

In an embodiment, the channel region includes a silicon layer, and the first S/D and the second S/D are doped with an extrinsic material configured to add resistance to the first S/D and the second S/D.

In an embodiment, the semiconductor device includes a logic device electrically coupling to the passive device, wherein the passive device is an electro-static discharge (ESD) lateral NPN device, an EDS lateral PNP device, an ESD N-channel field-effect transistor (NFET), an ESD P-Channel FET (PFET), or a bipolar junction transistor (BJT).

In an embodiment, the passive device includes a liner isolating the gate region from direct contact with the channel region.

In an embodiment, the first backside contact and the second backside contact couple the first S/D and the second S/D to a backside power delivery network (BSPDN), respectively.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1B illustrate a conventional planar ESD negative FET (ESDNFET) with ballasting resistance on source/drain regions.

FIGS. 2A-2B illustrate a conventional ESD lateral negative-positive-negative STI bound, ESDLNPN_STI) and the relationship between the current and voltage during an ESD event.

FIG. 3 illustrates a passive device of a semiconductor device, in accordance with some embodiments.

FIGS. 4A-4B illustrate a semiconductor device after the preparation of the starting wafer, in accordance with some embodiments.

FIG. 4C illustrates a top view of the active device after the preparation of the starting wafer, in accordance with some embodiments.

FIG. 4D illustrates a top view of the passive device after the preparation of the starting wafer, in accordance with some embodiments.

FIGS. 5A-5B illustrate a semiconductor device after patterning of the nanosheets, in accordance with some embodiments.

FIGS. 6A-6B illustrate a semiconductor device after the patterning of the shallow trench isolation, in accordance with some embodiments.

FIGS. 7A-7B illustrate a semiconductor device after the formation of the dummy gates, in accordance with some embodiments.

FIGS. 8A-8B illustrate a semiconductor device after the patterning of the dummy gates, in accordance with some embodiments.

FIGS. 9A-9B illustrate a semiconductor device after the formation of the spacers, in accordance with some embodiments.

FIGS. 10A-10B illustrate a semiconductor device after the formation of the placeholders and the source/drain regions, in accordance with some embodiments.

FIGS. 11A-11B illustrate a semiconductor device after the formation interlayer dielectric, in accordance with some embodiments.

FIGS. 12A-12B illustrate a semiconductor device after the removal of the dummy gates, in accordance with some embodiments.

FIGS. 13A-13B illustrate a semiconductor device after the formation of the replacement gates, in accordance with some embodiments.

FIGS. 14A-14B illustrate a semiconductor device after the middle of line processes, in accordance with some embodiments.

FIGS. 15A-15B illustrate a semiconductor device after the formation of the wafer flipping, in accordance with some embodiments.

FIGS. 16A-16B illustrate a semiconductor device after the removal of the etch stop layer, in accordance with some embodiments.

FIGS. 17A-17B illustrate a semiconductor device after the implantation of the source/drain regions, in accordance with some embodiments.

FIGS. 18A-18B illustrate a semiconductor device after the patterning of the source/drain regions, in accordance with some embodiments.

FIGS. 19A-19B illustrate a semiconductor device after the removal of the substrate, in accordance with some embodiments.

FIGS. 20A-20B illustrate a semiconductor device after the formation of the bottom interlayer dielectric, in accordance with some embodiments.

FIGS. 21A-21B illustrate a semiconductor device after the patterning of the backside contacts, in accordance with some embodiments.

FIGS. 22A-22B illustrate a semiconductor device after the metallization of the backside contacts, in accordance with some embodiments.

FIGS. 23A-23B illustrate a semiconductor device after the formation of the backside power delivery network, in accordance with some embodiments.

FIG. 24 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

The concepts herein relate to electrostatic discharge (ESD) devices. ESD devices are integral in safeguarding electronic circuits from abrupt electrical discharges that might cause damage. These devices typically feature numerous fingers or blocks of diffusions, which are segments of semiconductor material modified by diffusion processes to achieve specific electrical characteristics. To create an ESD device designers often connect hundreds or thousands of these blocks in parallel. In conventional ESD devices, particularly those employing architectures with hundreds of fingers (conductive paths within the device) arranged in a matrix of columns and rows, the lack of uniform current distribution can lead to significant performance issues. Typically, without adequate ballasting resistance, only one or two fingers may activate during an ESD event, leading to suboptimal dissipation of the electrostatic discharge and a consequent low failure threshold of the device.

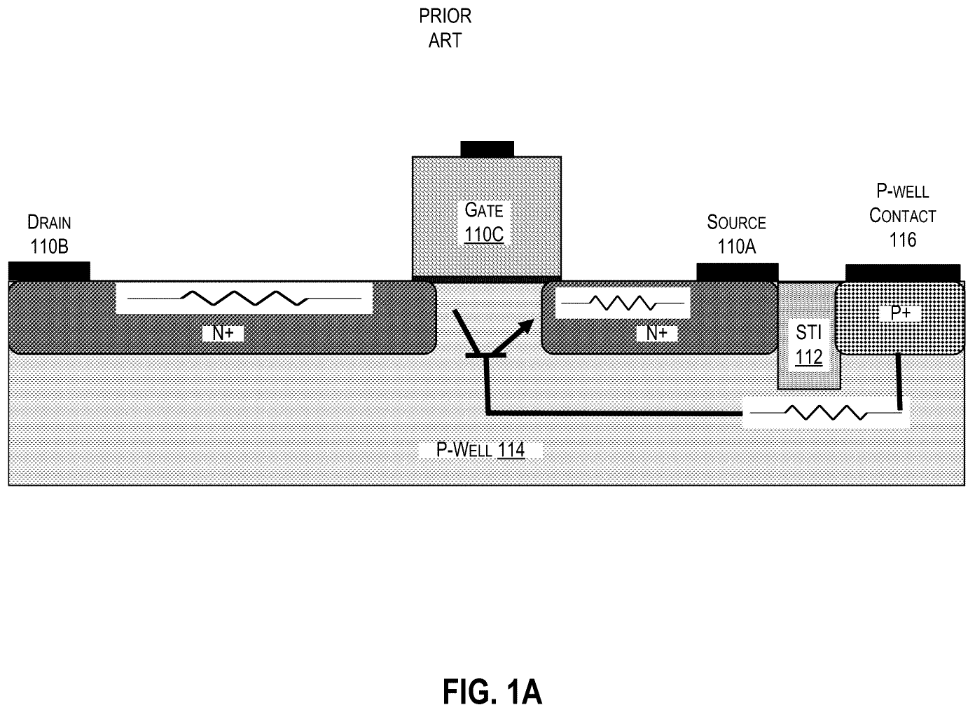

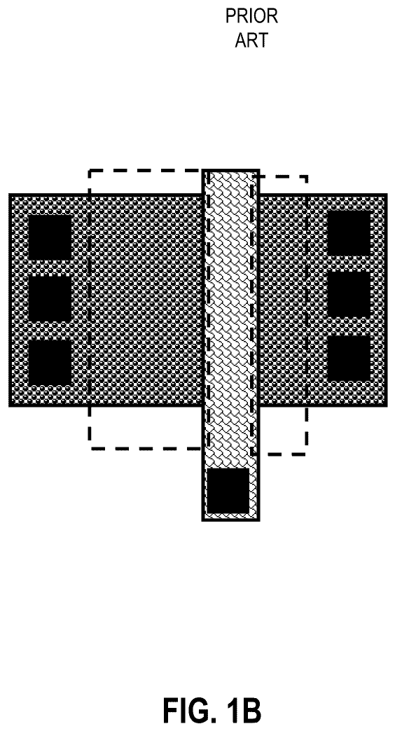

FIGS. 1A-1B illustrate a conventional planar ESD negative FET (ESDNFET) with ballasting resistance on source/drain regions. The conventional planar ESDNFET can include a source 110A, a drain 110B, a gate 110C, a shallow trench isolation, STI 112, a P-well 114 and a P-well contact 116. In a typical layout, the conventional planar NFET can include multiple columns and rows of fingers, with the width of each finger ranging from about 1 micrometer to about 20 micrometers, and the total width of the planar NFET ranging from about 200 micrometers to about 500 micrometers. A common issue in conventional devices such as the ESDNFET shown in FIG. 1A is uneven current distribution which leads to the activation of only a select few fingers, potentially compromising the device's integrity and effectiveness. In traditional ESDNFET device configurations, the resistance in the drain 110B (collector) and source 110A (emitter) regions ensures that the current is evenly spread across the width of the device. However, achieving uniform activation of all fingers simultaneously has posed challenges. Typically, a single finger within the array triggers first due to variations in threshold voltage or other localized conditions, which can lead to the premature failure of the device under high-stress conditions. FIG. 1B shows a top view of the ESDNFET device shown in FIG. 1A.

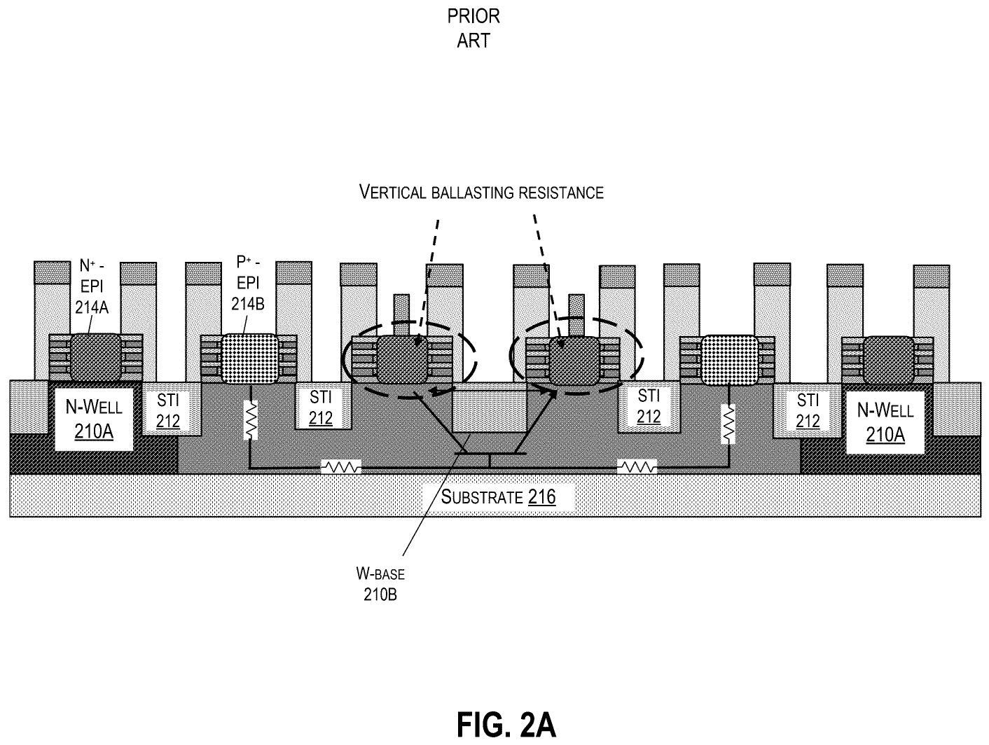

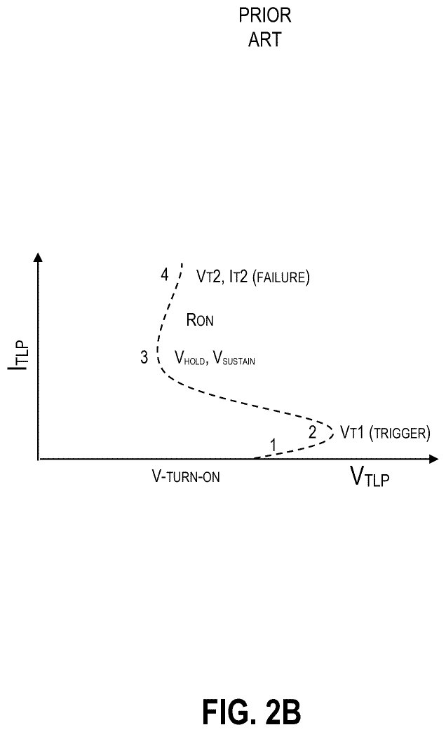

FIGS. 2A-2B illustrate a conventional ESD lateral negative-positive-negative STI bound, ESDLNPN_STI) and the relationship between the current and voltage during an ESD event. The conventional ESDLNPN_STI can include an N-well 210A, a base, WBase 210B, STI 212, collectors and emitters, N-epi 214A and P-epi 214B, and a substrate 216. In a conventional ESDLNPN_STI, or a conventional ESDLNPN, ESDLPNP, ESDNFET, and ESDPFET configurations, the traditional designs often incorporate ballasting resistance in a vertical orientation through the epitaxial layer, N-epi 214A and/or P-epi 214B, of the collector and emitter. However, the vertical ballasting restricts the amount of epitaxial material that can be utilized, thereby constraining the effectiveness of the resistance. Thus, the ballasting resistance extends only vertically and not horizontally through the emitter and collector regions. FIG. 2B shows the current and voltage during four stages of operations including leakage/pre-turn on 1, trigger/turn on 2, holding/sustaining 3, and failure 4. As can be seen, the voltage increases from turn on voltage (V-turn-on) to trigger voltage (Vt1), at which point the voltage sharply decreases to the holding/sustaining voltage (V_hold/Vsustain). The voltage then slightly increases again until the failure occurs at which point the voltage reaches failure voltage (Vt2).

In view of the above considerations, disclosed is a semiconductor device including an ESD device, with ballasting resistances incorporated into the drain (or collector) and source (or emitter) regions of each finger in the ESD device. The ballasting resistances are calculated and integrated to ensure they promote even current distribution across all fingers when the semiconductor device is subjected to ESD stress. This approach not only enables each finger to participate uniformly in handling the ESD event but also significantly enhances the overall robustness of the ESD protection mechanism.

By facilitating the uniform turn-on of all fingers, the integrated ballasting resistances offered by the disclosed semiconductor device can increase the failure current thresholds of the ESD device, thereby enhancing its efficacy in protecting sensitive semiconductor components against electrostatic discharges. Furthermore, the improved functionality can allow for a reduction in the overall size of the ESD device, as the enhanced efficiency of each finger can translate into reducing the size of the arrays. The integration of ballasting resistances as described offers an advancement in the design and functionality of ESD protection devices. The disclosed semiconductor device can improve the operational reliability of these devices and contribute to more compact and efficient designs at the same time, supporting the development of smaller and more robust semiconductor devices in various applications.

Accordingly, the teachings herein provide methods and systems of semiconductor device formation with integrated passive device into backside power delivery network (BSPDN). The techniques described herein may be implemented in a number of ways. Example implementations are provided below with reference to the following figures.

Example Semiconductor Device with Integrated Passive Device into BSPDN Structure

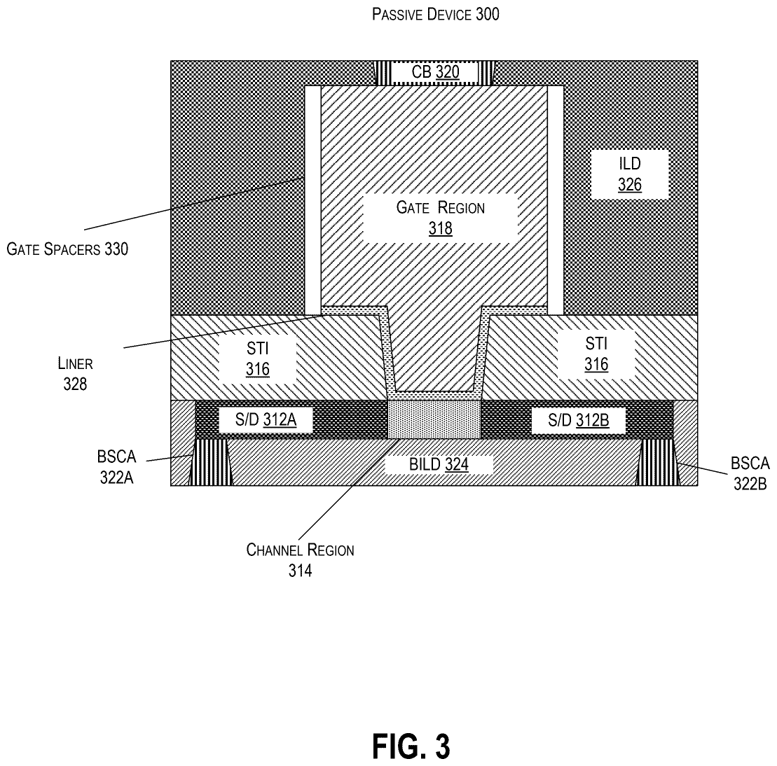

Reference now is made to FIG. 3, which are simplified cross-sections view of a semiconductor device, consistent with an illustrative embodiment. In various embodiments, the semiconductor device includes a passive device and a logic device. While for the sake of simplicity, only the passive device is shown in FIG. 3, it is worth mentioning that the passive device can be electrically connected to the logic device, which can be a transistor. It should be noted that, the logic device and the passive device may be depicted separately, however, the passive device and the logic device can be integrated on a same semiconductor device adjacent to each other.

The passive device 300 of the semiconductor device can include a first source/drain region 312A, a second source/drain region 312B, a channel region 314, shallow trench isolation, STI 316, a gate region 318, a gate contact, CB 320, a first backside contacts, BSCA 322A, a second backside contact, BSCA 322B, a bottom dielectric layer, BILD 324, an interlayer dielectric, ILD 326, a liner 328, and gate spacers 330.

Generally, the first source/drain region 312A and the second source/drain region 212B are two salient components that play relevant roles in the semiconductor device's operation. In various embodiments, the first source/drain region 312A and the second source/drain region 312B are regions within the semiconductor material, e.g., the passive device 300, where the current flows in and out of the passive device 300 of the semiconductor device. Source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied. The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

In some embodiments, the first source/drain region 312A is extended laterally between the channel region 314 and a first end 340A of the passive device 300. Similarly, in some embodiments, the second source/drain region 312B is extended laterally between the channel region 314 and a second end 340B of the passive device 300. The first end 340A and the second end 340B are located at the opposite sides of the passive device 300.

In some embodiments, the first source/drain region 312A and/or the second source/drain region 312B can be doped with an extrinsic material configured to add resistance to the first source/drain region 312A and/or the second source/drain region 312B. In traditional FET designs, the source/drain regions are typically doped to optimize conductivity and facilitate the flow of carriers from the source to the drain through the channel. However, controlling the resistance in these regions can offer significant advantages in terms of managing the electrical characteristics of the device. In some embodiments, the passive device 300 improves the performance and reliability of the semiconductor device through doping of the first source/drain region 312A and/or the second source/drain region 312B. The doping can involve the incorporation of an extrinsic material into the first source/drain region 312A and the second source/drain region 312B to increase their resistance. Such a modification aims to enhance the overall device control and efficiency in conducting electrical signals. By selectively doping the first source/drain region 312A and the second source/drain region 312B with a specific extrinsic material, the resistance within the source/drain regions can be finely tuned, which can enhance the modulation of the current flow and improve device performance under various operating conditions.

The doping process involves the introduction of chosen dopant materials into the first source/drain region 312A and the second source/drain region 312B, which can be selected based on their ability to create the desired level of resistance without compromising the intrinsic properties of the first source/drain region 312A and the second source/drain region 312B. The doping can ensure that the dopants are distributed in a controlled manner to achieve a uniform increase in resistance across the first source/drain region 312A and the second source/drain region 312B. In some embodiments, the increased resistance can help in reducing leakage currents, enhancing the switching characteristics, and improving the overall power efficiency of the passive device 300. In further embodiments, by configuring the first source/drain region 312A and the second source/drain region 312B to have tailored resistance levels, the passive device 300 can operate across a wide range of voltages and temperatures.

The channel region 314 can be extended horizontally between the first source/drain region 312A and the second source/drain region 312B and separate the first source/drain region 312A and the second source/drain region 312B. The channel region 314 can serve as a conductive pathway through which electronic carriers (electrons or holes) travel from the first source/drain region 312A to the second source/drain region 312B. The positioning and doping of the channel region 314 can ensure efficient charge carrier flow when the device is activated by an applied voltage across the gate terminal. In some embodiments, the channel region 314 is made of silicon. The channel region 314 can modulate its conductive state, from insulating to highly conductive, based on the gate voltage to allow the channel region 314 to act as an effective electronic switch. Moreover, the channel region's material composition, doping level, and geometric dimensions can be tailored to enhance the passive device's performance metrics such as on-state current, threshold voltage, switching speed, and power efficiency.

The STI 316 can be extended over the first source/drain region 312A and the second source/drain region 312B. In some embodiments, the gate region 318 is located over the STI 316 and the channel region 314. In an embodiment, portions of the STI can be recessed to divide the STI 316 into two separate parts. In such an embodiment, the gate region 318 is extended vertically through the STI 316 to fill the recessed portions of the STI. As a result, the gate region 318 can cover an upper surface of the channel region 314 which is covered by the liner 328. In other words, the liner 328 can separate, i.e., isolate, the channel region 314 from direct contact with the vertically extended portion of the gate region 318. The liner 328 can be further formed over portions of the upper surface of the STI 316 to isolate the STI 316 from direct contact with the channel region 314. Thus, in various embodiments, the channel region 314, the STI 316, and the gate region 318 are isolated from direct contact with each other via the liner 328.

In various embodiments, the gate region 318 serve as control elements that regulate the flow of current through the passive device 300. The gate region 318 can be composed of a conductive material. The gate region 318 can control the flow of electric current between the first source/drain region 312A and the second source/drain region 312B.

In some embodiments, by applying a voltage to the gate, the channel region's conductivity is modulated, allowing the passive device 300 to either allow or block the flow of current, which in turn enables the semiconductor device to act as electronic switches or amplifiers. The gate voltage can determine whether the semiconductor device is in an “on” or “off” state. When the gate voltage is below a certain threshold, the passive device 300 is in the “off” state, and the current flow between the source and drain is effectively blocked. On the other hand, when the gate voltage exceeds the threshold, the passive device 300 enters the “on” state, allowing current to flow through the channel region. In addition to acting as a switch, modulating the gate voltage can enable the gate region 318 to control the current flowing through the channel region, resulting in amplified output signals.

In an embodiment, the gate region 318 can enable the implementation of Boolean logic operations, such as AND, OR, and NOT, by controlling the flow of current based on the input voltages. Multiple semiconductor devices can be interconnected to form complex logic circuits, enabling the execution of various computational tasks in digital systems. In some embodiments, the gate region 318, along with other semiconductor device components, can facilitate the miniaturization and integration of electronic circuits. The ability to control the channel region's conductivity through the gate voltage allows for compact and highly efficient circuit designs.

The CB 320 can be located over the gate region 318. The CB 320 can establish connection between the gate region 318 and the back end of line (BEOL). The CB 320 can ensure efficient electrical routing and connectivity within the passive device 300. The fabrication of the CB 320 can involve lithography and etching processes to define the contact area. The CB 320 can be made using conductive materials such as copper (Cu) or tungsten (W).

The BSCA 322A and the BSCA 322B connect the first source/drain region 312A and the second source/drain region 312B to the backside power delivery network (BSPDN), respectively. Each of the BSCA 322A and BSCA 322B is a region on the backside of the passive device 300 where electrical connections are made. By establishing the electrical contacts, the BSCA 322A and BSCA 322B can ensure the proper functioning of the passive device 300 and facilitates electrical signal transmission. The BSCA 322A and BSCA 322B can serve as a thermal interface between the passive device 300 and a heat sink or other cooling mechanisms. In some embodiments, the BSCA 322A and BSCA 322B can help mitigate parasitic effects, such as substrate coupling or substrate noise, from the passive device 300. In further embodiments, the BSCA 322A and BSCA 322B can allow for increased integration density in the passive device 300. In an embodiment, the BSCA 322A and BSCA 322B can serve as means of providing electrostatic discharge protection to the passive device 300. Electrostatic discharge events can cause significant damage to sensitive electronic components and thus should be avoided. In some embodiments, the BSCA 322A is located at the first end 340A and connects the first source/drain region 312A to the BSPDN. Alternatively, in some embodiments, the BSCA 322B is located at the second end 340B and connects the second source/drain region 312B to the BSPDN.

In several embodiments, the BILD 324 can provide structural support to the passive device 300 by maintaining the mechanical integrity and stability of the passive device 300. The BILD 324 can further help prevent the warping, bending, or cracking of the substrate, particularly during the manufacturing process or subsequent handling. The BILD 324 can ensure that the passive device 300 remains mechanically robust and maintains its dimensional stability.

In an embodiment, the BILD 324 can also serve as a planarization layer in the passive device 300 fabrication process. As various layers are deposited and patterned on the front side of the passive device 300, irregularities or topographic variations may arise. The BILD 324 can be used to smoothen the surface, creating a more planar substrate for subsequent processing steps, such as metal interconnect deposition or bonding. In some embodiments, a low dielectric constant BILD material can be utilized to reduce signal delays, crosstalk, and power consumption in high-speed and high-frequency circuits. By optimizing the dielectric constant, the BILD 324 can contribute to improved overall passive device performance. In several embodiments, BILD 324 can facilitate wafer-level testing of the passive device 300. By providing electrical isolation between the active regions and the backside contact, individual passive device or elements on the passive device 300 can be electrically accessed and tested without interference from neighboring devices or components. This enables efficient and accurate wafer-level testing, ensuring quality control during semiconductor manufacturing.

The ILD 326 can be a layer of insulating material to electrically isolate and provide mechanical support between different layers of conducting and active components. The ILD 326 can enable efficient signal transmission, reduce crosstalk, and ensure the proper functioning of the passive device 300. In an embodiment, the ILD 326 can electrically isolate adjacent conducting layers or active components in the passive device 300. By providing insulation between different layers, the ILD 326 can prevent electrical shorts, reduce (e.g., minimize) leakage current, and ensure that signals are directed only along the desired pathways. In some embodiments, the ILD 326 can help reduce parasitic capacitance between adjacent metal interconnects or active devices and provide mechanical support to the passive device's structure.

The gate spacers 330 are an insulating material layer that surrounds and isolates the gate electrode of the semiconductor device. The gate spacers 330 electrically isolate the gate from a source/drain region to prevent unwanted electrical leakage. In some embodiments, the gate spacers 330 can help define the length of the gate beneath the gate electrode. In various embodiments, the gate spacers 330 can be made of silicon dioxide (SiO2), silicon nitride (Si3N4), or a high-k dielectric.

In some embodiments, the passive device 300 can include an ESD lateral NPN which includes a heavily doped n-type region (collector), a lightly doped p-type region (base), and a heavily doped n-type region (emitter). These regions are laterally arranged on the surface of the semiconductor substrate. When an ESD event occurs, a large transient voltage is applied across the device. The resulting high electric field causes the device to enter into avalanche breakdown, allowing it to conduct a large current to ground and dissipate the excess charge, protecting the integrated circuit from damage.

In an ESD lateral PNP device, the structure is similar but with opposite doping: a heavily doped p-type region (collector), a lightly doped n-type region (base), and a heavily doped p-type region (emitter). Similar to the lateral NPN device, when subjected to an ESD event, the lateral PNP device enters into avalanche breakdown, providing a low-impedance path for the discharge current to flow safely to ground, protecting the integrated circuit.

In some embodiments, the passive device 300 can include an ESD N-channel Field-Effect Transistor (ESD NFET), ESD P-channel Field-Effect Transistor (ESD PFET), or a Bipolar Junction Transistor (BJT). ESD NFET can includes heavily doped n-type source and drain regions, separated by a lightly doped n-type channel. During an ESD event, a high voltage at the gate forms an inversion layer in the channel, allowing current to flow from source to drain. ESD NFET provides low impedance for negative voltage transients, diverting current away from sensitive circuitry. ESD PFET, provides ESD protection against positive voltage transients, and includes heavily doped p-type source and drain regions, with a lightly doped p-type channel. When an ESD event occurs, a negative voltage applied to the gate forms an inversion layer, enabling current flow from drain to source. PFETs offer low impedance for positive voltage spikes, shunting current away from sensitive components. A BJT, features three layers-emitter, base, and collector-forming two P-N junctions. During an ESD event, BJTs enter into avalanche breakdown when voltage surpasses a threshold, allowing a large current flow either from collector to emitter (NPN) or emitter to collector (PNP).

Example Fabrication of a Semiconductor Device with Integrated Passive Device into BSPDN Substrate

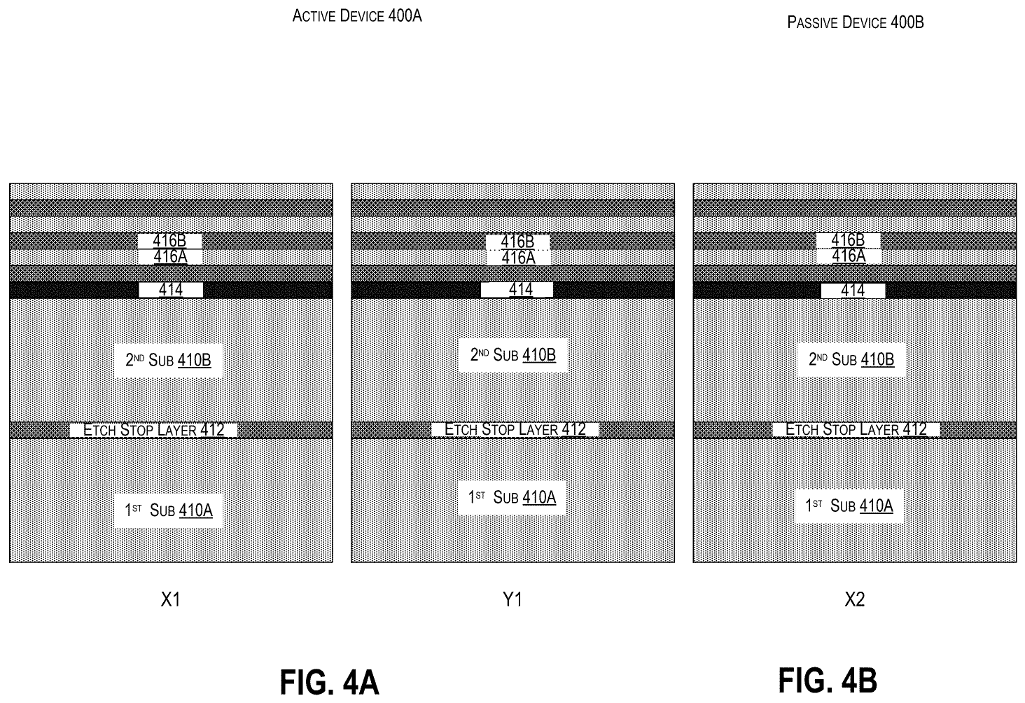

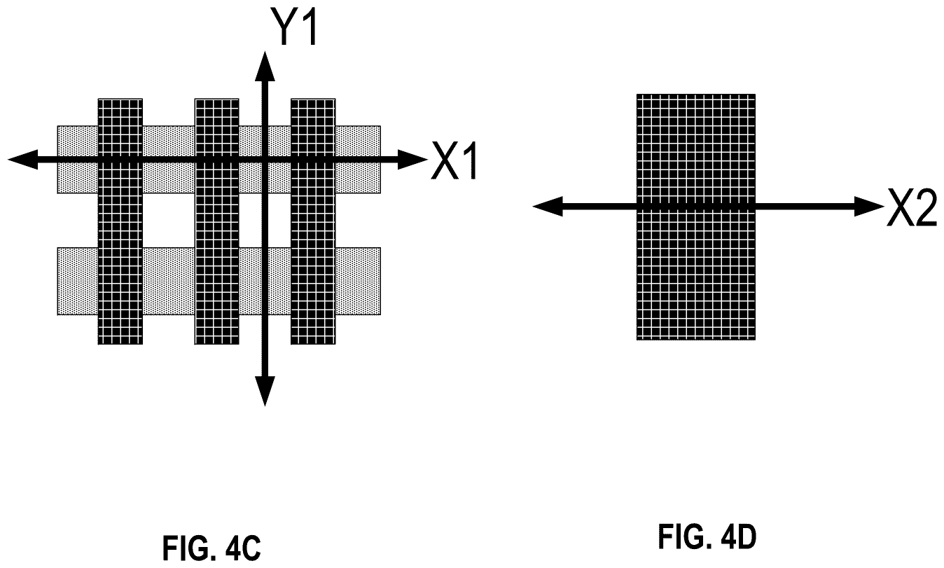

With the foregoing description of an example semiconductor device, it may be helpful to discuss an example process of manufacturing the same. To that end, FIGS. 4-23 illustrate various acts in the manufacture of a semiconductor device, consistent with illustrative embodiments.

As noted above, the passive device shown in FIG. 3 can be electrically connected to the active device, which can be a transistor. FIGS. 4-23 depict acts of fabrication of the active device and the passive device. Figures denoted by A show the acts of fabrication of the active device in an X1 cross-section, figures denoted by B show the acts of fabrication of the active device in a Y1 cross-section, and figures denoted by C show the acts of fabrication of the passive device in an X2 cross-section. FIG. 4C illustrates a top view of the active device to depict the X1 and Y1 cross-sections, and FIG. 4D illustrates a top view of the passive device to depict the X2 cross-section.

Reference now is made to FIGS. 4A-4B, which are simplified cross-section views of a semiconductor device, after the preparation of the starting wafer, consistent with an illustrative embodiment. As noted above, the semiconductor device includes an active device 400A and a passive device 400B. While for the sake of avoiding clutter, the active device 400A and the passive device 400B are depicted separately, it should be noted that the active device 400A and the passive device 400B can be integrated on a same semiconductor device adjacent to each other. Further, the active device 400A depicted in FIG. 4A is a logic device, and the passive device 400B depicted in FIG. 4B is an ESD device.

The active device 400A and the passive device 400B can include a first substrate 410A, a second substrate 410B, an etch stop layer 412, a high-Ge SiGe layer 414, and a plurality of alternating layers of Si 416A and SiGe 416B.

In the illustrative example depicted in FIGS. 4A-4B, the semiconductor device is depicted as being on silicon as the first substrate 410A and the second substrate 410B, while it will be understood that other types as the first substrate 410A and the second substrate 410B can be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the first substrate 410A and the second substrate 410B can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, the etch stop layer 412 is formed between the first substrate 410A and the second substrate 410B. The etch stop layer 412 can be a thin layer of material incorporated into the structure of the semiconductor device to provide a selective barrier against etching processes, preventing further removal of underlying materials during fabrication. The etch stop layer 412 can enable precise control over the etching depth and help define the desired device dimensions. The etch stop layer 412 can further provide a stopping point for the etching process, ensuring that specific layers or regions are not etched beyond a certain point, leading to accurate patterning and control of critical features. The etch stop layer 412 can create a distinct separation between different layers or components within the device structure, and prevent the undesired etching of underlying layers or materials, enabling the creation of complex, multi-layered structures with well-defined interfaces and boundaries. In some embodiments, the etch stop layer 412 acts as a protective barrier for sensitive or delicate materials to shield such materials from aggressive etchants, preventing damage or degradation during subsequent fabrication steps.

In some embodiments, prior to forming the etch stop layer 412, the first substrate 410A and/or the second substrate 410B is prepared by cleaning and removing any impurities or oxide layers. The etch stop layer 412 is deposited onto the first substrate 410A using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 412 can then be selectively etched, stopping at a predetermined depth, while protecting the underlying layers. After the etching process, the remaining photoresist can be removed through stripping techniques. While in some embodiments, SiGe is used to form the etch stop layer 412, in some embodiments, silicon nitride (SiN), silicon oxide (SiO2), or silicon oxynitride (SiON) can be used as the etch stop layer 412.

The alternating layers of Si 416A and SiGe 416B can be alternating, vertically-oriented sheets, which can drive current in a small footprint area. In some embodiments, the alternating layers of Si 416A and SiGe 416B are used as precursors to form the nanosheets and can include three-dimensional structures in the gate, which are extended from one source/drain region to another source/drain region. The high-Ge SiGe layer 414 can be a sacrificial layer which is removed during the subsequent acts of fabrication. In some embodiments, the SiGe layers of the alternating layers of Si 416A and SiGe 416B includes about 30% Ge, while the high-Ge SiGe layer 414 includes about 55% Ge.

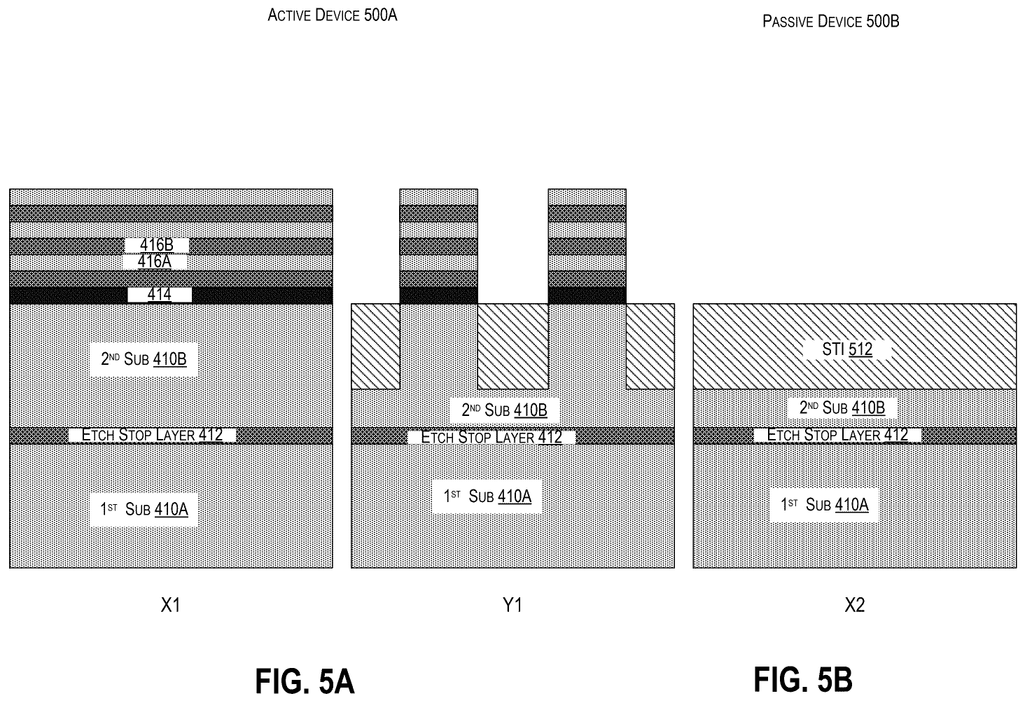

FIGS. 5A-5B illustrate a semiconductor device after the removal of the substrate, in accordance with some embodiments. In some embodiments, the alternating layers of Si 416A and SiGe 416B on the active device 500A and the passive device 500B are patterned by removing portions of the alternating layers of Si 416A and SiGe 416B along with the high-Ge SiGe layer 414, and forming the nanosheet gates. The removal of the alternating layers of Si 416A and SiGe 416B can be stopped once portions of the second substrate 410B are removed. Subsequently, STI 512 can be formed within the recessed portions of the second substrate 410B.

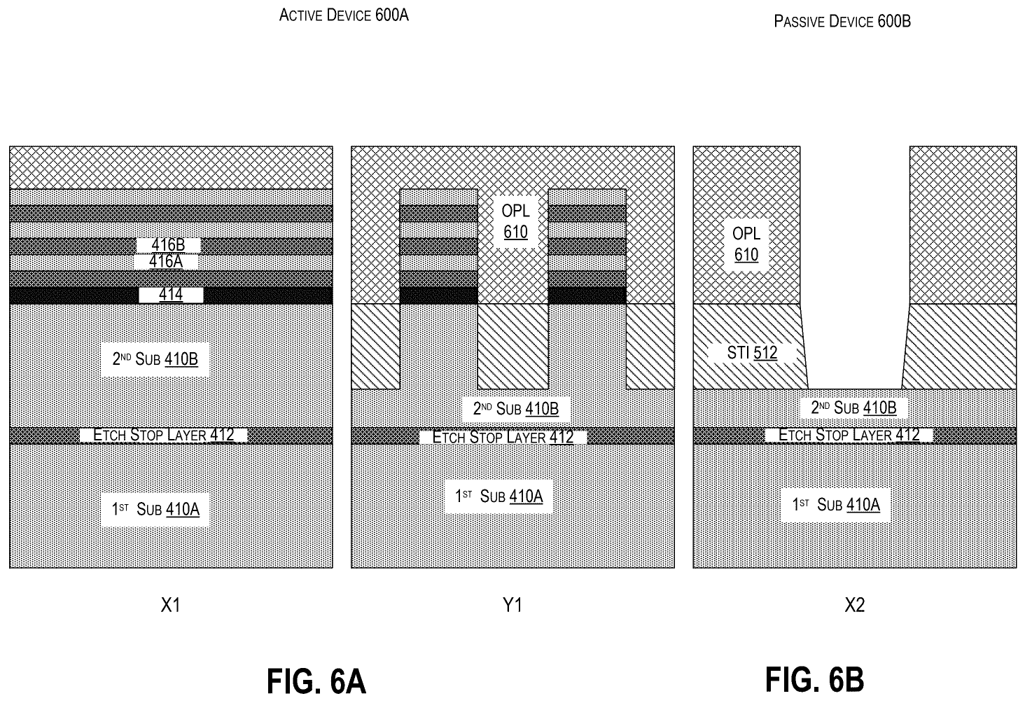

FIGS. 6A-6B illustrate a semiconductor device after the pattering of the STI, in accordance with some embodiments. In some embodiments, an organic planarization layer, OPL 610, is formed over the active device 600A and the passive device 600. The OPL 610 can include a photo-sensitive organic polymer having a light-sensitive material that, when exposed to electromagnetic radiation, is chemically altered and thus configured to be removed using a developing solvent. For example, in some embodiments, the photo-sensitive organic polymer can be polyacrylate resin, epoxy resin, phenol resin, polyamide resin, polyimide resin, unsaturated polyester resin, polyphenylenether resin, polyphenylenesulfide resin, or benzocyclobutene. In some embodiments, the OPL 610 can include any organic polymer and a photoactive compound having a molecular structure that can attach to the molecular structure of the organic polymer. In some embodiments, the OPL 610 material is selected to be compatible with an overlying antireflective coating and/or an overlying photoresist. In some embodiments, the OPL 610 can be applied using spin coating technology, although other techniques are within the contemplated scope of the present disclosure. Portions of the OPL 610 and the STI 512 over the passive device 600B are removed to expose the top surface of the second substrate 410B. The active device 600A can remain intact and covered by the OPL 610.

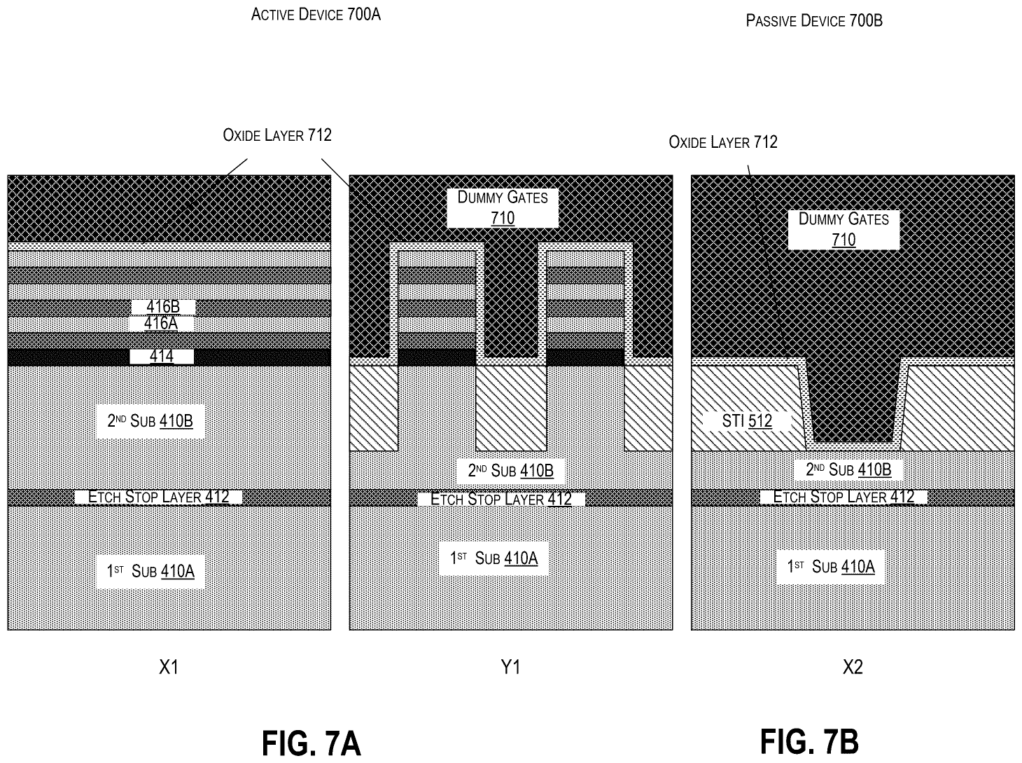

FIGS. 7A-7B illustrate a semiconductor device after the formation of the dummy gates, in accordance with some embodiments. In some embodiments, the OPL is removed from the active device 700A and the passive device 700B. An oxide layer 712 can then form over the surface of the active device 700A and the passive device 700B, followed by formation of dummy gates 714 over the oxide layer 712.

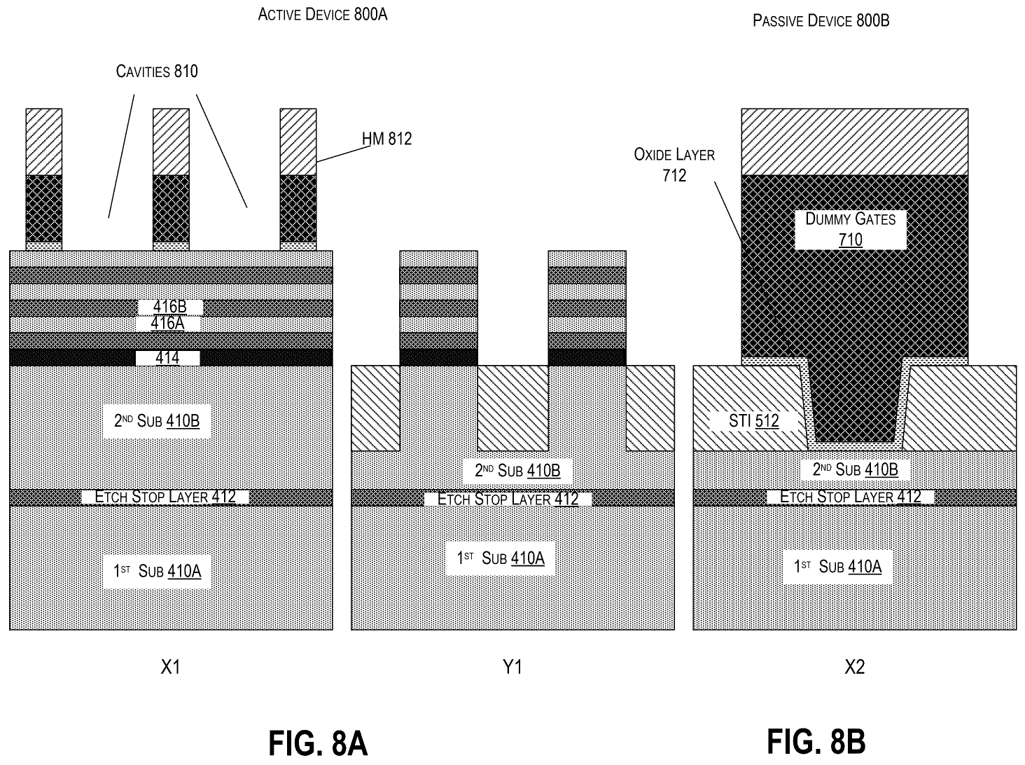

FIGS. 8A-8B illustrate a semiconductor device after the patterning of the dummy gates, in accordance with some embodiments. In some embodiments, the dummy gates 714 are patterned to form a plurality of cavities 810 between the dummy gates 714 across the X1 cross section of the active device 800A, while the dummy gates are removed across the Y1 cross section. In some embodiments, portions of the dummy gates at the first end and the second end of the passive device 800B are removed, while the middle portion of the dummy gates are remained intact. A hard mask, HM 812, can be formed over each of the dummy gates 714.

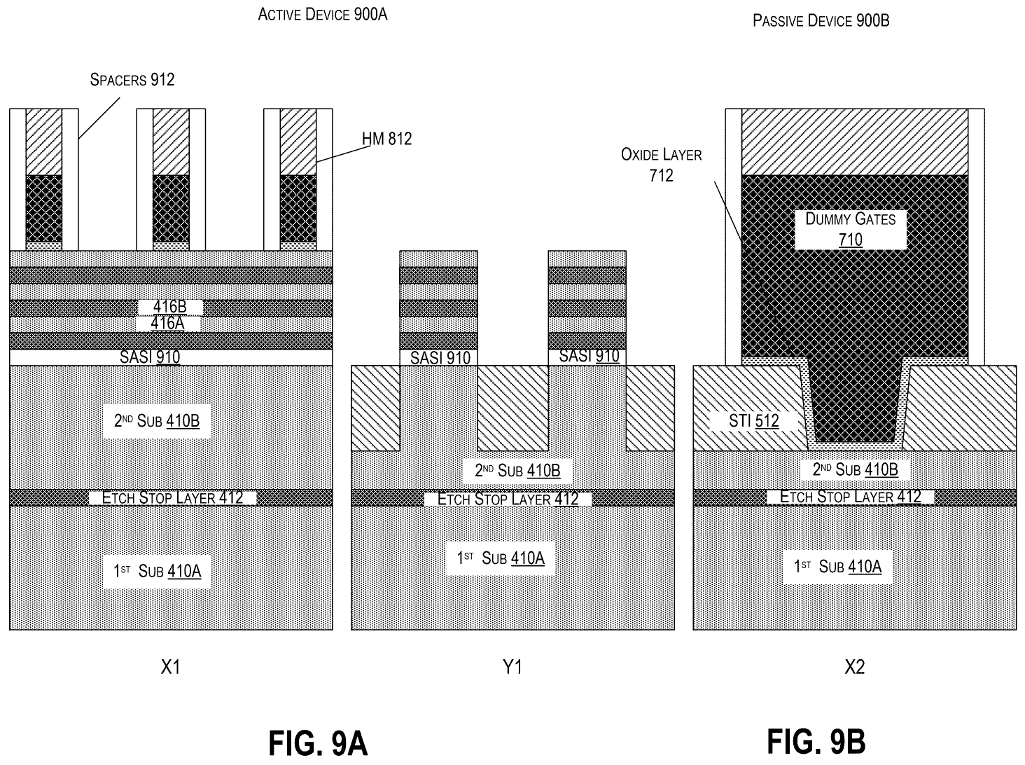

FIGS. 9A-9B illustrate a semiconductor device after the formation of the spacers, in accordance with some embodiments. In some embodiments, the high-Ge SiGe layer 414 are removed and a self-aligned substrate isolation, SASI 910, is formed over the second substrate 410B on the active device 900A. Spacers 912 can be formed over the sidewalls of the dummy gates 714 and the HM 812 in active device 900A and the passive device 900B. The spacers 912 can be thin insulating layers or materials which can help control the effective channel length of the semiconductor device. In an embodiment, the spacers 912 can allow for control over the channel's conductive properties, including resistance and carrier mobility, which can contribute to improved performance of the semiconductor device. The spacers 912 can be a low-k material.

In some embodiments, the spacers 912 can act as insulating layers between the gate regions and the source/drain regions. That is, the spacers 912 can help prevent current leakage or short circuits between the gate regions and the source/drain regions. Such isolation can help maintain the integrity of the semiconductor device's electrical operation and prevent unintended current flow that could negatively impact the performance of the semiconductor device and reliability.

In further embodiments, the spacers 912 can be utilized to modulate the overlapping capacitance between the gate regions and the source/drain regions. Overlapping capacitance can affect the device's electrical characteristics, such as threshold voltage and switching behavior. Thus, by adjusting the thickness and material properties of the spacers 912 the overlapping capacitance can be optimized, which can allow for better control and modulation of the device's behavior. In several embodiments, the spacers 912 can help mitigate the short-channel effects by physically separating the gate region from the source/drain regions. To that end, the spacers 912 can create a barrier that restricts the extension of the electric field into the channel region. This mitigation can improve the semiconductor device's performance, reduce power consumption, and enhance overall device reliability.

In an embodiment, the spacers 912 can serve as barriers that prevent the lateral diffusion of dopant atoms from the source/drain regions, into the channel region during the doping process. Such diffusion can alter the channel characteristics and compromise the semiconductor device's performance. By confining the dopant diffusion, the spacers 912 can contribute to maintaining the desired passive device's characteristics and electrical behavior. In some embodiments, the spacers 912 can be formed over the sidewalls of the gate regions. The spacers 912 can be formed by deposition techniques. Alternatively, the spacers 912 can be formed by etching or selectively epitaxially growing the spacers 912 over the sidewalls of the dummy gates 714 and the HM 812. In various embodiments, the spacers 912 can include SiGe.

SASI 910 can be utilized to isolate the active device's structure from the substrate electrically. The SASI 910 can provide isolation and reduce parasitic capacitance and leakage currents between the active device 900A and the substrate layer. SASI 910 is a dielectric material that can help improve the active device 900A performance and reliability by minimizing undesirable effects such as substrate leakage and latch-up.

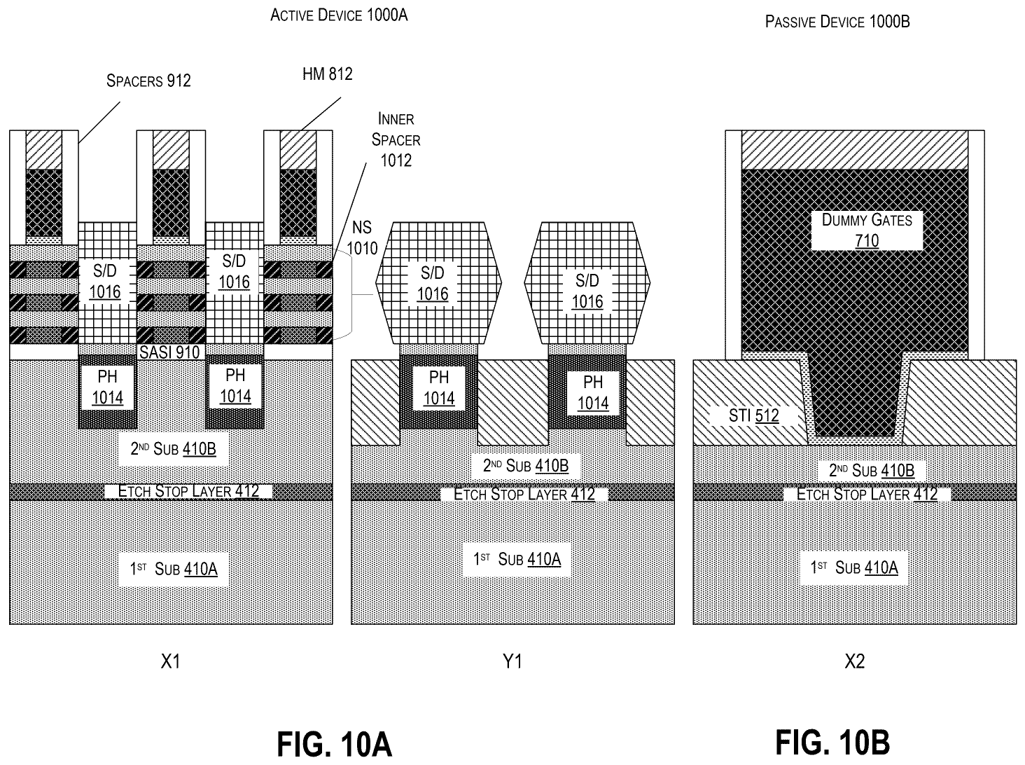

FIGS. 10A-10B illustrate a semiconductor device after the formation of the source/drain regions and the placeholders, in accordance with some embodiments. In some embodiments, the nanosheet gates, NS 1010, can be formed on the active device 1000A by the alternating layers of Si 414A and SiGe 414B, in which sidewalls of the SiGe layers are indented and covered by the inner spacers 1012. The SiGe layers can subsequently be removed and replaced with gate region materials. The inner spacers 1012 are insulating material layers that isolate the NS 1010. The inner spacers 1012 can electrically isolate the individual nanosheets from each other to prevent unwanted electrical leakage. In some embodiments, the inner spacers 1012 are made of silicon dioxide (SiO2), silicon nitride (Si3N4), or a high-k dielectric. In an embodiment, the inner spacer 1012, similar to the spacers 912, can act as insulating layers between the gate regions and the source/drain regions. In various embodiments, the inner spacer 1012 can be the same as the spacers 912, which are formed over portions of the gate regions confined between the NS 1010. The source/drain regions can form over the placeholders 1014 in the Active device 1000A.

In some embodiments, portions of the SASI and the second substrate 410B are removed and placeholders 1014 are formed in the recessed portions. The portions of the second substrate 410B can be removed by a reactive ion etching (RIE) technique. Generally, RIE is a dry etching process used in semiconductor device fabrication to remove materials from the surface of a substrate selectively. In some embodiments, RIE can involve the use of reactive ions and plasma to react with and remove specific materials chemically. In an embodiment, the RIE process begins by placing the semiconductor device inside a vacuum chamber. The chamber is then evacuated to create a low-pressure environment. Reactive gases, which can include a combination of a chemically reactive gas and an inert gas, are introduced into the chamber. The chemically reactive gas, such as fluorine-based gases (e.g., CF4, SF6) or chlorine-based gases (e.g., Cl2), can react with the material to be etched, i.e., the second substrate, Si, while the inert gas, e.g., argon, can help to control the ion bombardment.

In some embodiments, radiofrequency or microwave power is applied to create a plasma within the chamber. In such embodiments, power excites the gas molecules, causing them to ionize and form a plasma of reactive ions and electrons. The plasma can include reactive ions that chemically react with the silicon. The reactive ions bombard the substrate surface, break chemical bonds and remove silicon. In various embodiments, the RIE process can be selective, meaning it can mainly affect the target material, i.e., silicon, while leaving other materials, such as masking layers or underlying layers, relatively unaffected.

In some embodiments, to achieve selective etching, an etch mask can be applied on the substrate surface prior to the RIE process. The etch mask protects certain regions from etching, allowing the reactive ions to remove the exposed material selectively. The etching process can be controlled to achieve specific etch profiles, such as vertical sidewalls or tapered structures. Parameters such as gas composition, pressure, power, and process duration are adjusted to achieve the desired etch characteristics. In some embodiments, endpoint detection techniques, such as optical emission spectroscopy or laser interferometry, can be used to determine when the etching process has reached a desired endpoint. This ensures accurate control of the etch depth and prevents over-etching. After the etching process is completed, the substrate can be cleaned to remove any residue or by-products from the etching. Cleaning can involve rinsing with solvents or plasma cleaning to ensure the substrate's surface is free from contaminants. Subsequently, the removed portions of the second substrate 410B can be filled with the placeholders 1014. The placeholders 1014 can be epitaxially grown. In some embodiments, the source/drain regions 1016 are formed above the placeholders 1014 in the active device 1000A. During this step, the passive device 1000B can remain intact.

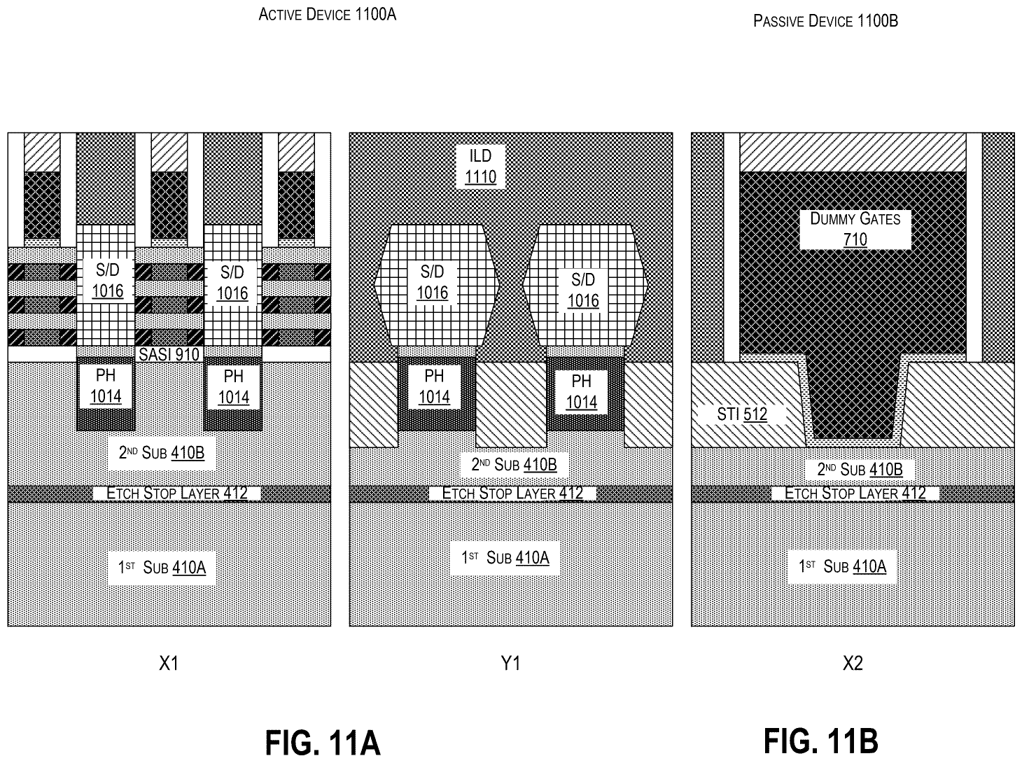

FIGS. 11A-11B illustrate the semiconductor device after the formation of the interlayer dielectric, in accordance with some embodiments. In some embodiments, the HM can be removed from the active device 1100A and the passive device 1100B and the interlayer dielectric, ILD 1110, is formed over the source/drain regions 1016 in the active device 1100A, and over the sidewalls of the spacers 912 in the passive device 1100B. A chemical-mechanical polishing (CMP), which involves the planarization of the semiconductor device's surface after each layer deposition, can be performed to ensure a flat and smooth surface for subsequent layers.

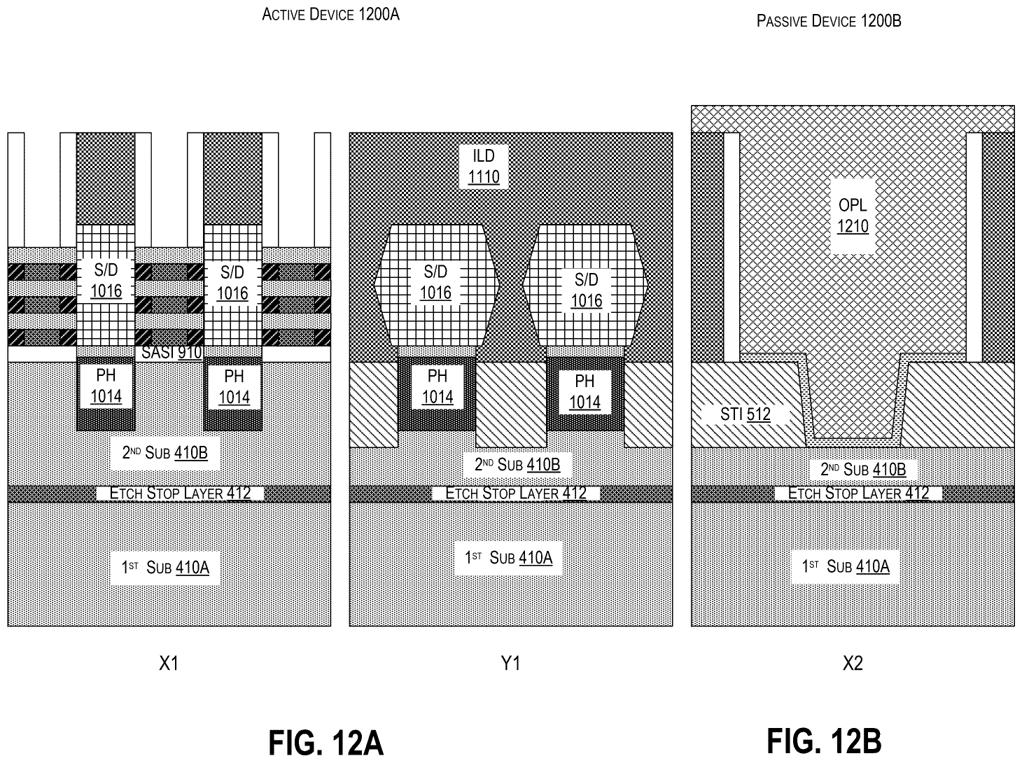

FIGS. 12A-12B illustrate the semiconductor device after the removal of the dummy gates, in accordance with some embodiments. In some embodiments, the dummy gates are removed from the active device 1200A and the passive device 1200B. Afterwards, an OPL 1210 can be formed over the passive device 1200B and the oxide layer can be removed from the surface of the NS.

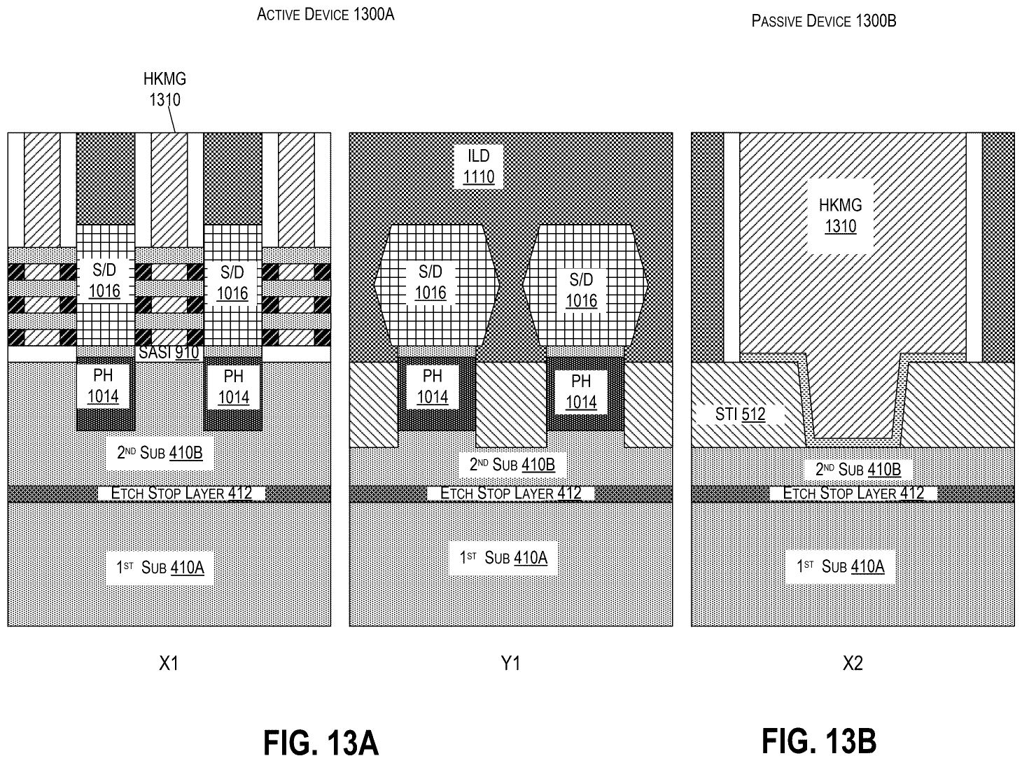

FIGS. 13A-13B illustrate the semiconductor device after the formation of the replacement metal gate, in accordance with some embodiments. In some embodiments, OPL is removed by an ashing process. The sacrificial placeholders can be released from the active device 1300A. Subsequently, the metal gate, HKMG 1310, is formed over the active device 1300A and the passive device 1300B. A replacement metal gate (RMG) process can be used to fabricate metal gate electrodes. In some embodiments, RMG can involve the replacement of the SiGe with a metal material, which can offer improved electrical performance and scalability. The metal gates can provide electrostatic control of the channel region, reduce leakage currents, and improve the semiconductor device's performance. In some embodiments, the metal gates can further provide improved control over the work function, enable matching of threshold voltages, and reduce semiconductor device variability.

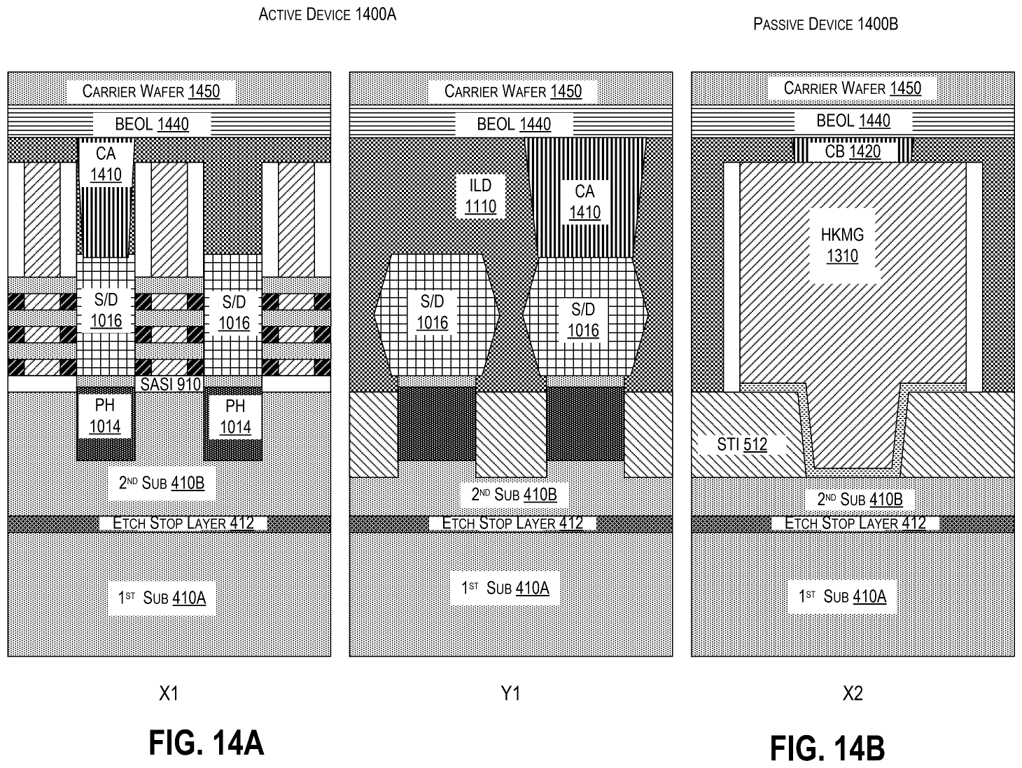

FIGS. 14A-14B illustrate the semiconductor device after the formation of the middle of line and the back end of line, in accordance with some embodiments. In some embodiments, the middle of line, MOL, is performed in the active device 1400A and the passive device 1400B. The formation of the MOL involves the formation of the metal layers and interconnects that connect various components and transistors on the semiconductor device. In several embodiments, during the MOL process, multiple metal layers are deposited and patterned on the semiconductor device. These metal layers serve as electrical connections, such as contacts CA 1410, and gate contact, CB 1420, which allow signals to pass between different parts of the integrated circuit. In addition to metal layers, insulating layers (often made of low-k dielectric materials, such as ILD) can be deposited between metal layers to isolate them from each other and prevent electrical interference. In some embodiments, advanced lithography and patterning techniques are used to define the intricate patterns of metal lines and vias (vertical connections between metal layers) during the MOL process.

In some embodiments, back end of line, BEOL 1440, is formed over the MOL, followed by formation of the carrier wafer 1450. The BEOL 1440 can include metal interconnects, e.g., wires and metal lines, and insulating layers that connect the various components of the semiconductor device and enable them to function as a cohesive unit.

In various embodiments, carrier wafer bonding, also known as wafer-to-wafer bonding or chip-to-wafer bonding, is performed to join two semiconductor devices together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices. The metal layer can be deposited or transferred onto one or both semiconductor device surfaces, and the semiconductor devices can then be brought into contact and subjected to temperature and pressure to create a metallic bond.

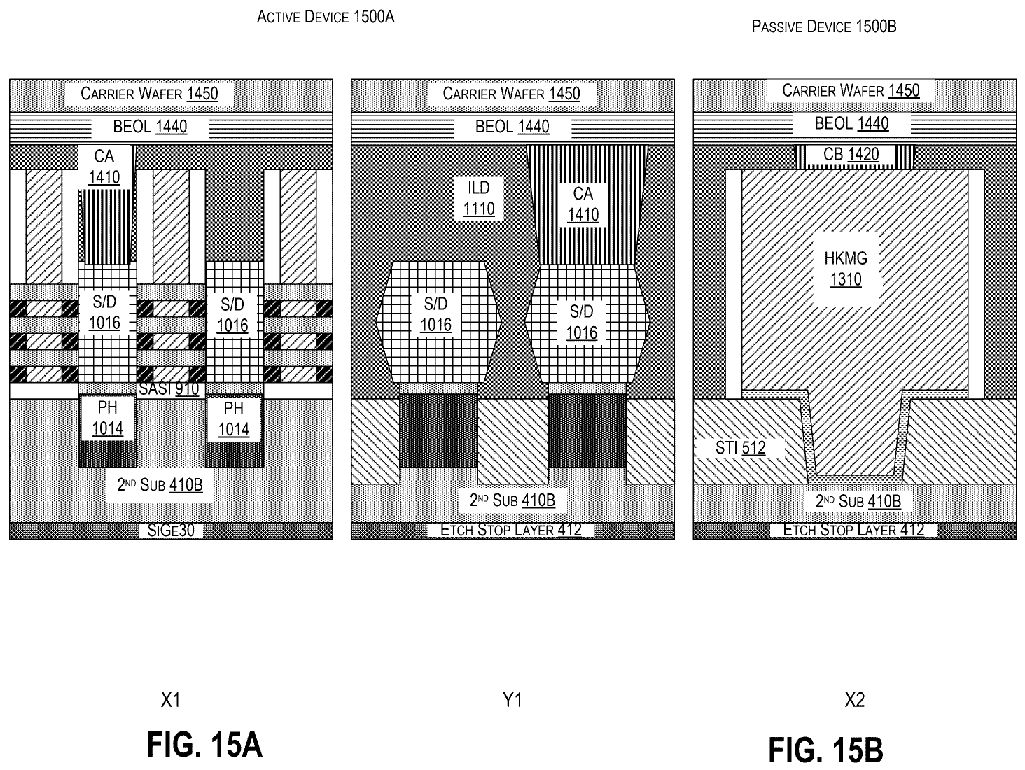

FIGS. 15A-15B illustrate the semiconductor device after the wafer flip, in accordance with some embodiments. In some embodiments, the wafer is flipped and the first substrate is removed from the active device 1500A and the passive device 1500B. It should be noted that, for the sake of simplicity, the semiconductor device is not shown as flipped. In some embodiments, the second substrate are removed and the etch stop layer 412 is exposed.

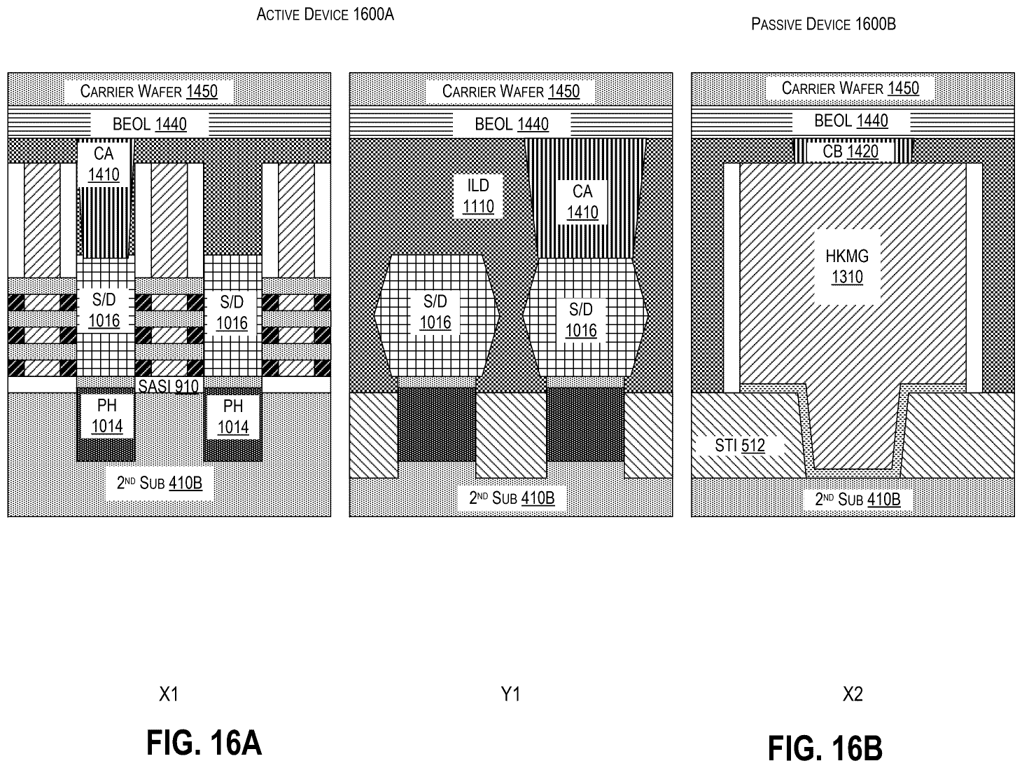

FIGS. 16A-16B illustrate the semiconductor device after the removal of the etch stop layer, in accordance with some embodiments. In some embodiments, the etch stop layer is removed and the second substrate 410B is exposed in the active device 1600A and the passive device 1600B.

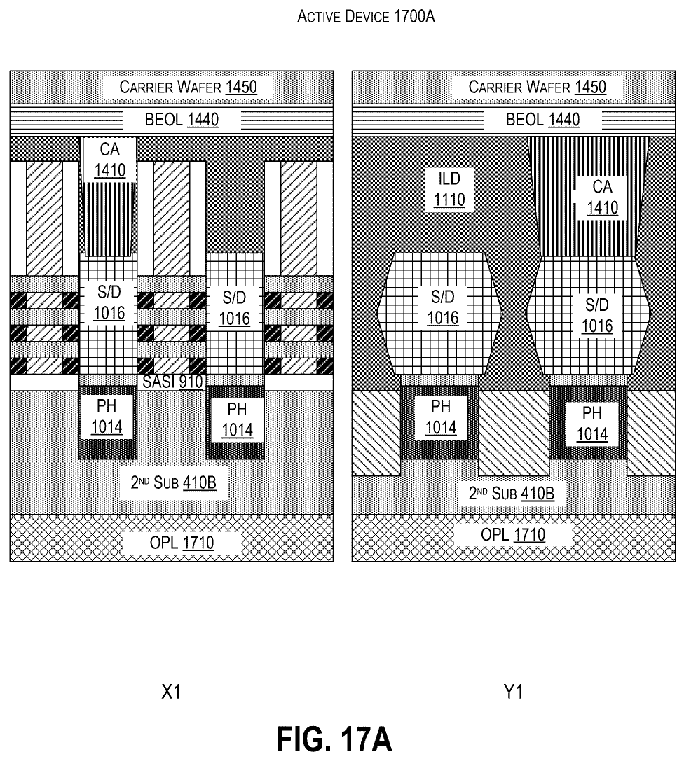

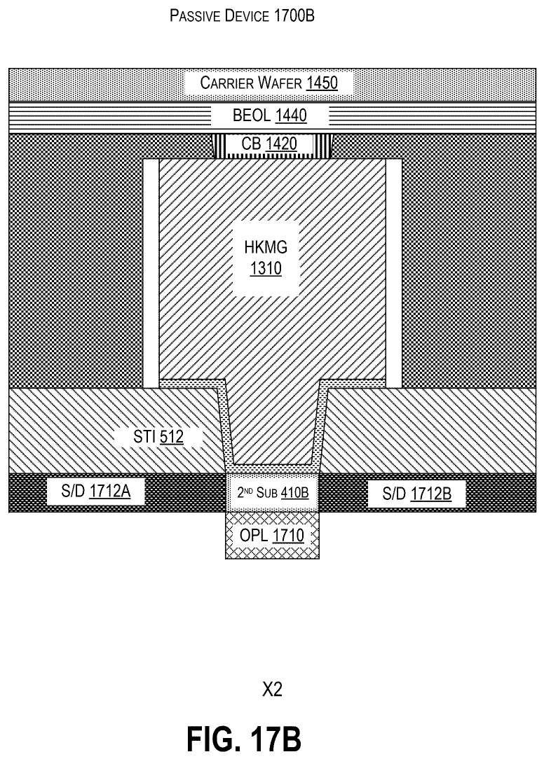

FIGS. 17A-17B illustrate the semiconductor device after the source/drain region implantation, in accordance with some embodiments. In some embodiments, an OPL 1710 is formed over the second substrate 410B on the active device 1700A and the passive device 1700B. Portions of the OPL 1710 over the STI 512 can be removed and the first source/drain region 1712A and the second source/drain region 1712B can be formed over the STI 512 by a hot implantation method, which can be followed by a laser annealing.

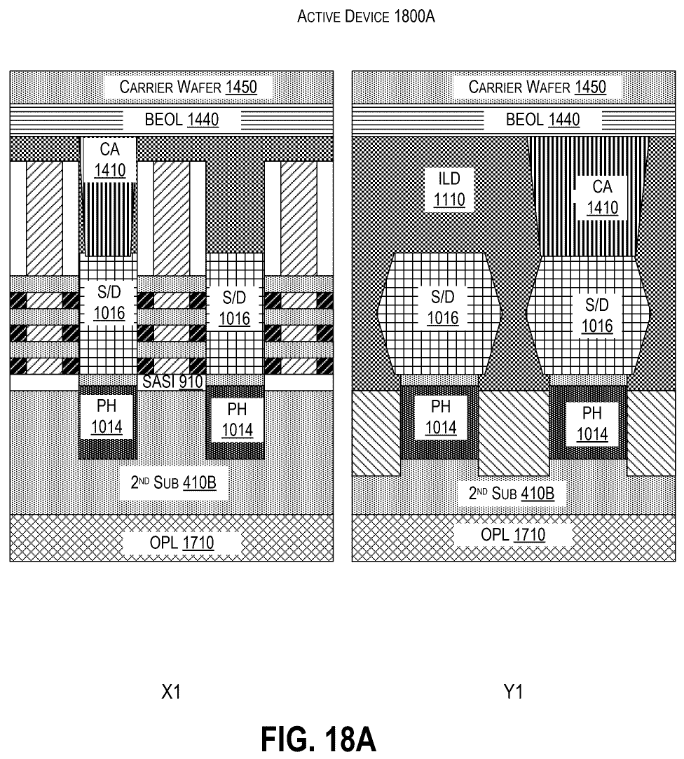

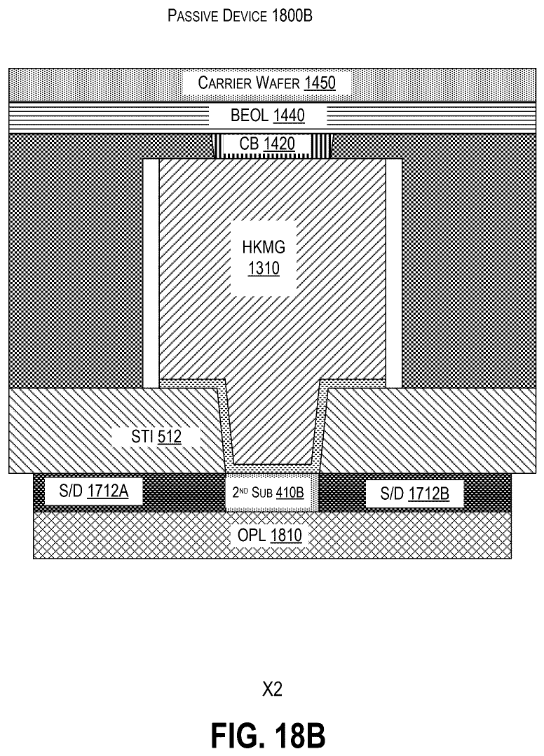

FIGS. 18A-18B illustrate the semiconductor device after the patterning of the source/drain regions, in accordance with some embodiments. In some embodiments, an OPL 1810 is formed over the first source/drain region 1712A and the second source/drain region 1712B, leaving the portions of the first source/drain region 1712A and the second source/drain region 1712B which are in the vicinity of the first end 340A and the second end 340B exposed and uncovered. While the active device 1800A is intact, the uncovered portions of the first source/drain region 1712A and the second source/drain region 1712B can be removed to pattern the first source/drain region 1712A and the second source/drain region 1712B in the passive device 1800B.

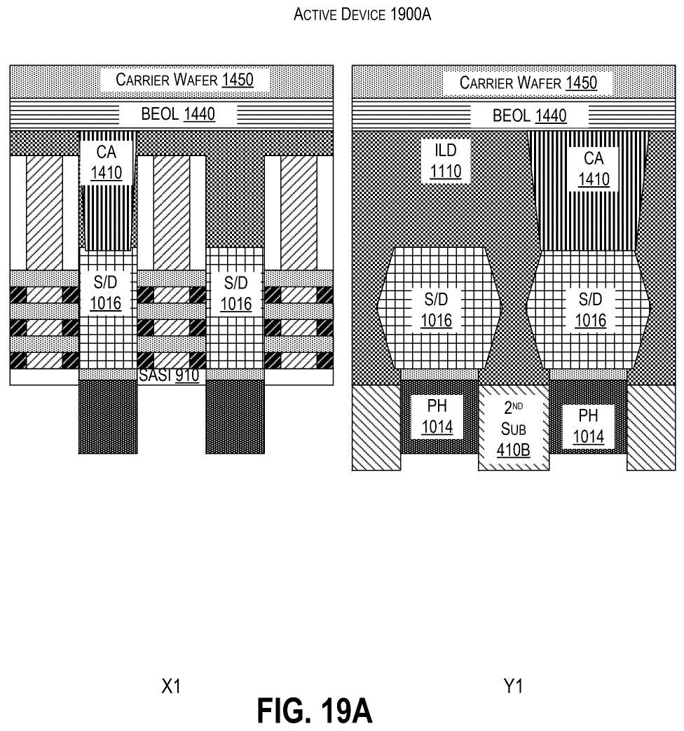

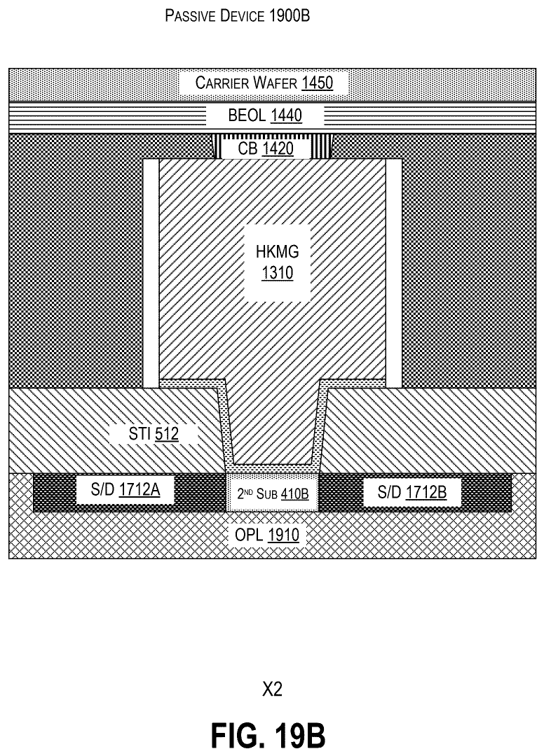

FIGS. 19A-19B illustrate the semiconductor device after the removal of the substrate, in accordance with some embodiments. In some embodiments, an OPL 1910 can be formed over the removed portions of the first source/drain region 1712A and the second source/drain region 1712B in the passive device 1900B. The second substrate 410B can then be removed from the active device 1900A to expose the STI 512, the placeholders 1014 and the SASI 910.

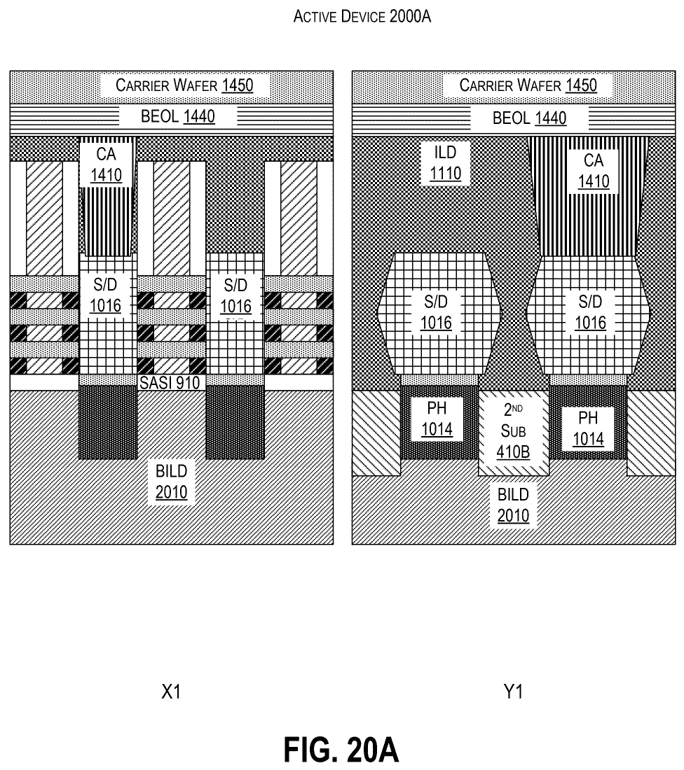

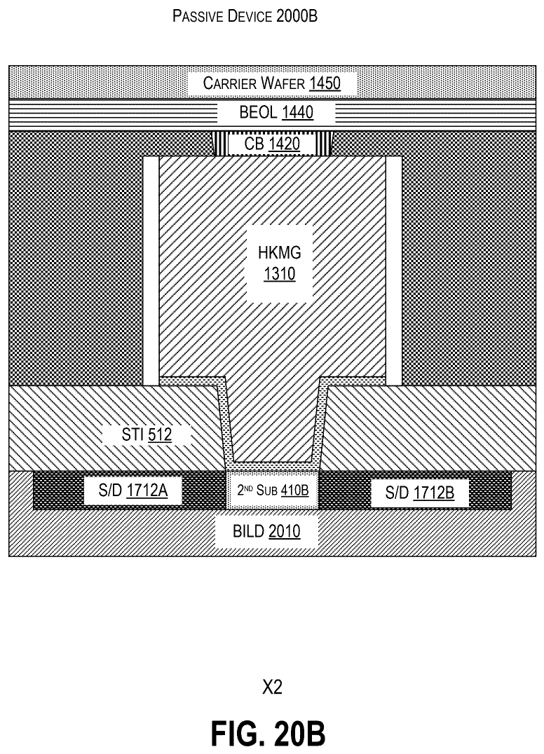

FIGS. 20A-20B illustrate the semiconductor device after the formation of the bottom interlayer dielectric, in accordance with some embodiments. In some embodiments, the OPL is removed and the bottom ILD, BILD 2010, is formed over the active device 2000A and the passive device 2000B. The BILD 2010 can be an insulating material or layer used to isolate and provide electrical insulation between the device's active regions and other components, and to prevent unwanted electrical contact between the active regions and the other components. In various embodiments, the BILD 2010 can act as a protective layer, shielding the active regions of the semiconductor device from external contaminants, moisture, and mechanical stress. The BILD 2010 can further help prevent physical damage, such as scratches or particle contamination, which could adversely affect semiconductor device performance. Additionally, the BILD 2010 can act as a barrier against moisture ingress, which can cause corrosion and degradation of the semiconductor device's components.

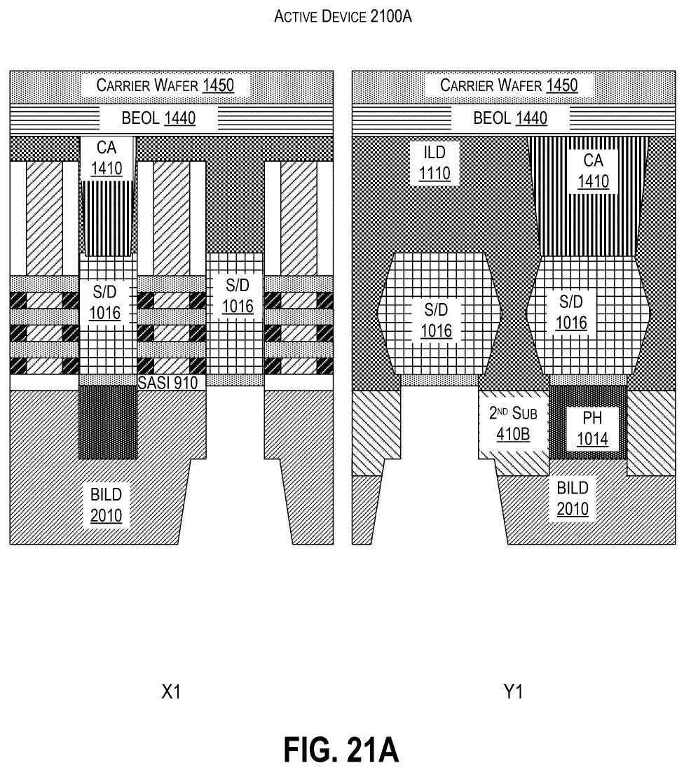

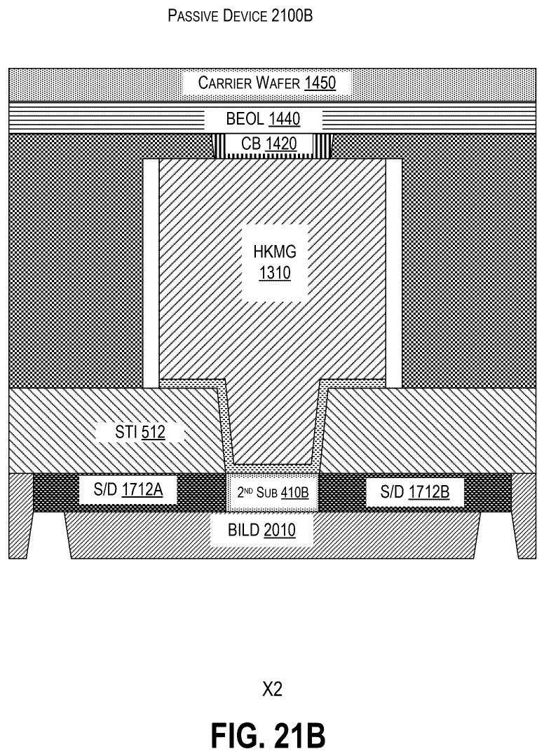

FIGS. 21A-21B illustrate a semiconductor device after the patterning of the backside contact of the active device and the passive device, in accordance with some embodiments. In some embodiments, the backside of the active device 2100A is patterned by removing portions of the BILD 2010 and the placeholders 1014, and exposing the SASI 910. It should be noted that, the placeholder which is below the source/drain region with the CA 1410 remains intact in the active device 2100A. Similarly, the backside of the passive device 2100B is patterned by removing portions of the BILD 2010 and exposing the first source/drain region 1712A and the second source/drain region 1712B.

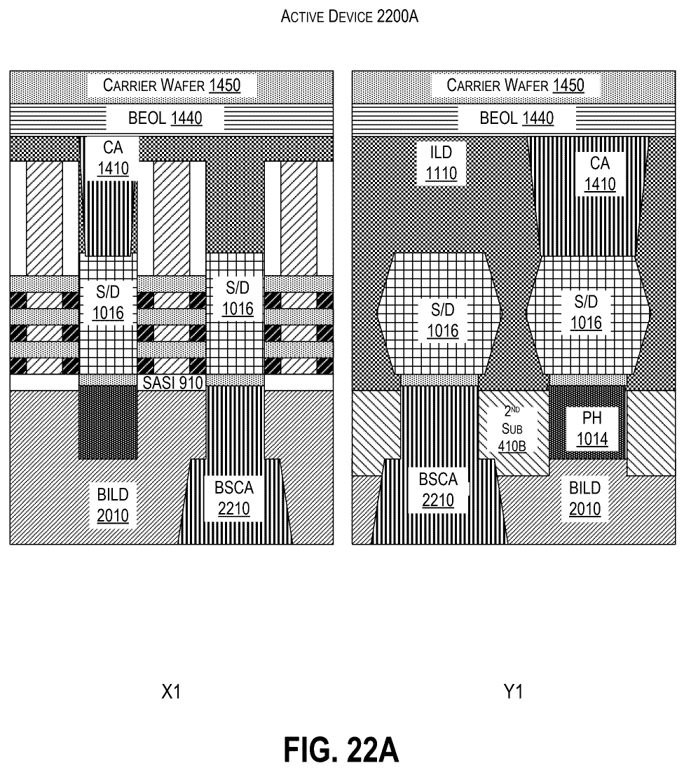

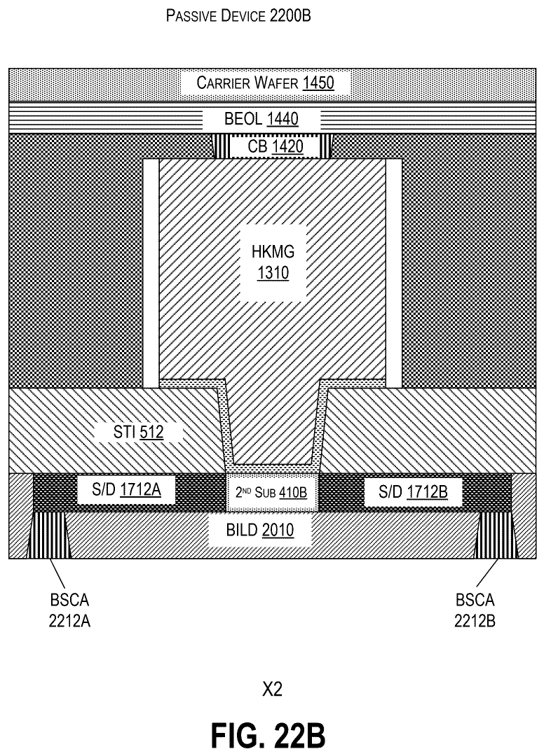

FIGS. 22A-22B illustrate a semiconductor device after the backside contact metallization, in accordance with some embodiments. In some embodiments, the backside contact, BSCA 2210, is formed in the active device 2200A by filling the recessed areas by a suitable metal. The BSCA 2210 can be encapsulated by the BILD 2010. Similarly, in some embodiments, the backside contacts, BSCA 2212A and BSCA 2212B, are formed in the passive device 2200B by filling the recessed areas by a suitable metal. The BSCA 2212A and BSCA 2212B can be encapsulated by the BILD 2010.

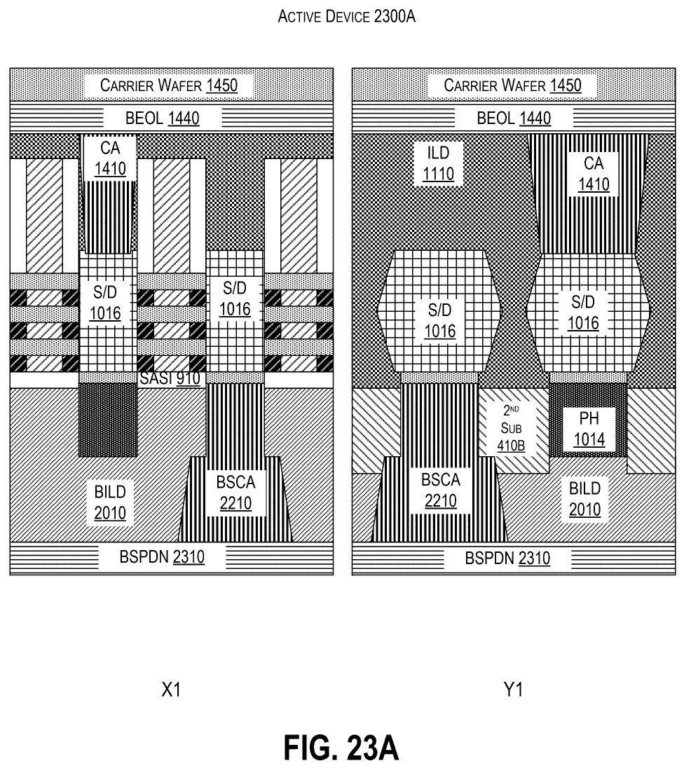

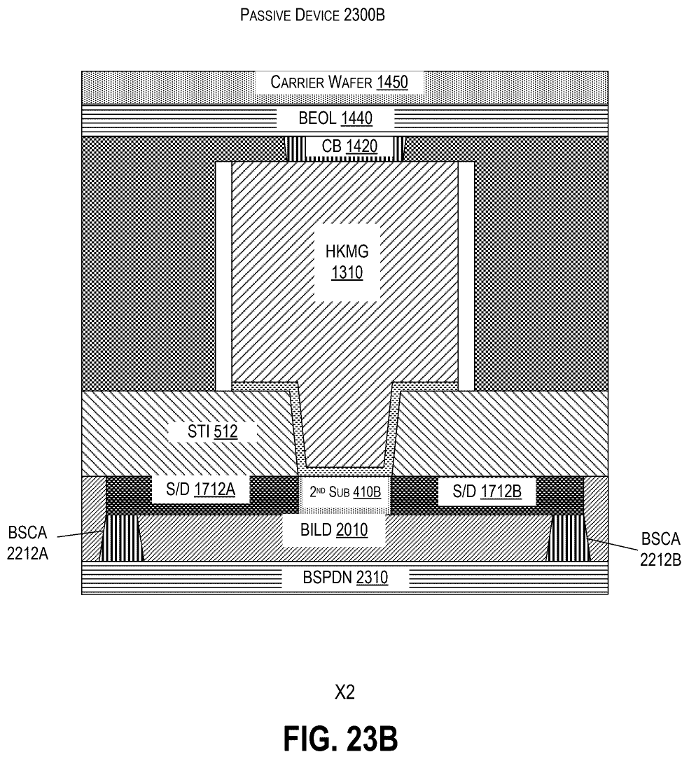

FIGS. 23A-23B illustrate a semiconductor device after the formation of a backside power delivery network, in accordance with some embodiments. In some embodiments, a backside power delivery network, BSPDN 2310, is formed over the BSCA 2210 in the active device 2300A and over BSCA 2212A and BSCA 2212B in the passive device 2300B. The BSPDN 2310 can connect the semiconductor device to other devices.

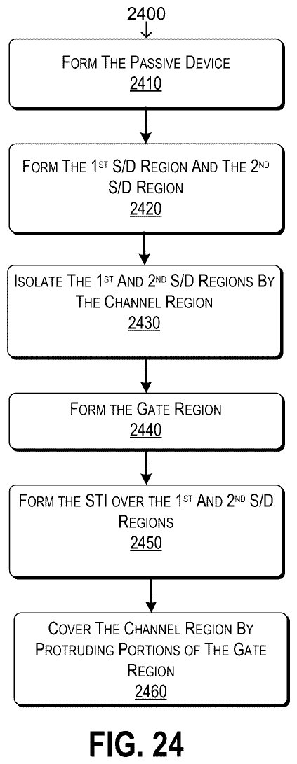

FIG. 24 illustrate a block diagram of a method 2400 for forming the semiconductor device, in accordance with some embodiments. As shown by block 2410, the passive devices formed.

As shown by block 2420, the first source/drain region and the second source/drain region are formed.

As shown by block 2430, the first source/drain region and the second source/drain region are isolated by the channel region.

As shown by block 2440, the gate region is formed above the first source/drain region and the second source/drain region. The first source/drain region can be extended laterally between the channel region and a first end, and the second source/drain region can be extended laterally between the channel region and a second end.

As shown by block 2450, the STI is formed and extended laterally over the first source/drain region and the second source/drain region.

As shown by block 2460, the upper surface of the channel region is covered by vertically protruding portions of the gate region through the STI.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a passive device comprising:
a channel region separating a first source/drain region (S/D) and a second S/D,
wherein:
the first S/D is extended laterally between the channel region and a first end; and
the second S/D is extended laterally between the channel region and a second end, a shallow trench isolation (STI) extended over the first S/D and the second S/D; and
a gate region over the STI and the channel region,
wherein portions of the gate region are extended vertically through the STI and cover an upper surface of the channel region.

2. The semiconductor device of claim 1, wherein the passive device further comprises a liner isolating the gate region from direct contact with the STI and the channel region.

3. The semiconductor device of claim 1, wherein the channel region includes a silicon layer.

4. The semiconductor device of claim 1, wherein the first S/D and the second S/D are doped with an extrinsic material configured to add resistance to the first S/D and the second S/D.

5. The semiconductor device of claim 1, wherein the passive device further comprises:
a first backside contact connected to a bottom surface of first S/D on the first end; and
a second backside contact coupled to a bottom surface of the second S/D on the second end.

6. The semiconductor device of claim 5, wherein the first backside contact and the second backside contact couple the first S/D and the second S/D to a backside power delivery network (BSPDN), respectively.

7. The semiconductor device of claim 1, wherein the passive device is an electro-static discharge (ESD) lateral NPN device, an EDS lateral PNP device, an ESD N-channel field-effect transistor (NFET), an ESD P-Channel FET (PFET), or a bipolar junction transistor (BJT).

8. The semiconductor device of claim 1, further comprising a logic device electrically connected to the passive device.

9. A method for fabrication of a semiconductor device, the method comprising:
forming a passive device comprising:
forming a first source/drain region (S/D) and a second S/D;
isolating the first S/D and the second S/D by a channel region;
forming a gate region above the first S/D and the second S/D;
forming the first S/D extended laterally between the channel region and a first end;
forming the second S/D extended laterally between the channel region and a second end;
forming a shallow trench isolation (STI) extended laterally over the first S/D and the second S/D; and
covering an upper surface of the channel region by vertically protruding portions of the gate region through the STI.

10. The method of claim 9, further comprising forming a liner isolating the gate region from direct contact with the STI and the channel region.

11. The method of claim 9, further comprising doping the first S/D and the second S/D with an extrinsic material configured to add resistance to the first S/D and the second S/D.

12. The method of claim 9, further comprising:
electrically coupling a first backside contact to a bottom surface of first S/D on the first end; and
electrically coupling a second backside contact to a bottom surface of the second S/D on the second end.

13. The method of claim 12, further comprising electrically connecting the first backside contact and the second backside contact to the first S/D and the second S/D to a backside power delivery network (BSPDN), respectively.

14. The method of claim 9, further comprising forming a logic device electrically coupled to the passive device.

15. A semiconductor device, comprising:
a passive device comprising:
a channel region separating a first source/drain region (S/D) and a second S/D,
wherein:
the first S/D is extended laterally between the channel region and a first end; and
the second S/D is extended laterally between the channel region and a second end, a gate region over the channel region;
a first backside contact coupled to a bottom surface of first S/D on the first end; and
a second backside contact coupled to a bottom surface of the second S/D on the second end,
wherein portions of the gate region cover an upper surface of the channel region.

16. The semiconductor device of claim 15, further comprising:
a shallow trench isolation (STI) extended over the first S/D and the second S/D; wherein:
the gate region is extended over the STI; and
portions of the gate region are extended vertically through the STI.

17. The semiconductor device of claim 15, wherein:
the channel region includes a silicon layer; and
the first S/D and the second S/D are doped with an extrinsic material configured to add resistance to the first S/D and the second S/D.

18. The semiconductor device of claim 17, further comprising a logic device electrically coupling to the passive device, wherein the passive device is an electro-static discharge (ESD) lateral NPN device, an EDS lateral PNP device, an ESD N-channel field-effect transistor (NFET), an ESD P-Channel FET (PFET), or a bipolar junction transistor (BJT).

19. The semiconductor device of claim 15, wherein the passive device further comprises a liner isolating the gate region from direct contact with the channel region.

20. The semiconductor device of claim 15, wherein the first backside contact and the second backside contact couple the first S/D and the second S/D to backside power delivery network (BSPDN), respectively.
